(19) United States
(12) Patent Application Publication
(10) Pub. No.: US 2026/0122978 A1
(43) Pub. Date: Apr. 30, 2026

(54) SEMICONDUCTOR DEVICES WITH STRESSOR ELEMENTS

(71) Applicant: TEXAS INSTRUMENTS INCORPORATED, Dallas, TX (US)

(72) Inventor: Mahalingam Nandakumar, Richardson, TX (US)

(21) Appl. No.: 18/933,473

(22) Filed: Oct. 31, 2024

(51) Int. Cl. H01L 29/78; H01L 21/762; H01L 29/66

(52) U.S. Cl. CPC H10D 30/795; H10D 30/0281; H10D 30/65; H10D 30/797; H10W 10/014; H10W 10/17

(57) ABSTRACT

Semiconductor devices and fabrication methods thereof are described. For example, a semiconductor device includes a semiconductor layer, a first source region, a first drain region, a second source region and a second drain region disposed in the semiconductor layer, a gate electrode disposed above the semiconductor layer and surrounding the first source region, the first drain region, the second source region and the second drain region, and a stressor embedded in the semiconductor layer adjacent to the first drain region, the first source region, the second drain region and the second source region. The first source region and the first drain region, and the second source region and the second drain region are aligned with one another in a first direction. The first source region and the second drain region, and the second source region and the first drain region are aligned with one another in a second direction.

### TECHNICAL FIELD

The present disclosure relates to the field of semiconductor transistors, and more particularly, but not exclusively, to laterally diffused metal oxide semiconductor (LDMOS) transistors.

### BACKGROUND

LDMOS devices are field-effect transistors (FETs) designed for high power applications. In an LDMOS device, the drain and source have a relatively large spacing between them, as compared with metal oxide semiconductor (MOS) devices designed for other applications, and lateral diffusions are used to produce a well-controlled channel region under the gate. The operational performance of LDMOS devices is generally affected by parameters including, for example, a specific on-resistance (Rsp) and a breakdown voltage (BV). One design goal of LDMOS devices is to decrease Rsp and increase BV, or at least to improve one parameter without adversely affecting the other parameter.

### SUMMARY

The present disclosure describes semiconductor devices with stressor elements and methods of fabrication thereof. This summary is not an extensive overview of the disclosure. Rather, a purpose of the summary is to present some examples of the present disclosure in a simplified form as a prelude to a more detailed description that is presented later.

In some examples, a semiconductor device includes a semiconductor layer, a first source region disposed in the semiconductor layer, a first drain region disposed in the semiconductor layer, a second source region disposed in the semiconductor layer, a second drain region disposed in the semiconductor layer, a gate electrode disposed above the semiconductor layer and surrounding the first source region, the first drain region, the second source region and the second drain region. The semiconductor device further includes a stressor embedded in the semiconductor layer, the stressor being adjacent to the first drain region, the first source region, the second drain region and the second source region. The first source region and the first drain region are aligned with one another in a first direction, and the second source region and the second drain region are aligned with one another in the first direction. The first source region and the second drain region are aligned with one another in a second direction, and the second source region and the first drain region are aligned with one another in the second direction.

In some other examples, a semiconductor device includes a semiconductor layer, a first source region disposed in the semiconductor layer, a first drain region disposed in the semiconductor layer, a second source region disposed in the semiconductor layer, a second drain region disposed in the semiconductor layer, a gate electrode disposed above the semiconductor layer and surrounding the first source region, the first drain region, the second source region and the second drain region. The semiconductor device also includes one or more stressors, each of the one or more stressors being embedded in or disposed over at least one of the first source region, the first drain region, the second source region and the second drain region. The first source region and the first drain region are aligned with one another in a first direction, and the second source region and the second drain region are aligned with one another in the first direction. The first source region and the second drain region are aligned with one another in a second direction, and the second source region and the first drain region are aligned with one another in the second direction.

In some other examples, a method includes forming a first source region in a semiconductor layer, forming a first drain region in the semiconductor layer, forming a second source region in the semiconductor layer, forming a second drain region in the semiconductor layer, forming a gate electrode above the semiconductor layer and surrounding the first source region, the first drain region, the second source region and the second drain region, and forming one or more stressors. The first source region and the first drain region are aligned with one another in a first direction, and the second source region and the second drain region are aligned with one another in the first direction. The first source region and the second drain region are aligned with one another in a second direction, and wherein the second source region and the first drain region are aligned with one another in the second direction. The one or more stressors apply stress in the first direction and the second direction.

### BRIEF DESCRIPTION OF THE DRAWINGS

FIG. 1A is a plan view (or a layout view) of a semiconductor device with shallow trench isolation stressor elements in accordance with examples of the present disclosure;

FIGS. 1B and 1C are respective cross-sectional views of the semiconductor device of FIG. 1A;

FIG. 1D is a flow diagram of a method of forming the semiconductor device with shallow trench isolation stressor elements shown in FIGS. 1A-1C in accordance with examples of the present disclosure;

FIG. 2A is a plan view (or a layout view) of a semiconductor device with stressor elements embedded in source and drain regions in accordance with examples of the present disclosure;

FIGS. 2B and 2C are respective cross-sectional views of the semiconductor device of FIG. 2A;

FIG. 2D is a flow diagram of a method of forming the semiconductor device with the stressor elements embedded in source and drain regions shown in FIGS. 2A-2C in accordance with examples of the present disclosure;

FIG. 3A is a plan view (or a layout view) of a semiconductor device with stress liner elements in accordance with examples of the present disclosure;

FIGS. 3B and 3C are respective cross-sectional views of the semiconductor device of FIG. 3A;

FIG. 3D is a flow diagram of a method of forming the semiconductor device with the stress liner elements shown in FIGS. 3A-3C in accordance with examples of the present disclosure;

FIG. 4A is a plan view (or a layout view) of a semiconductor device with shallow trench isolation stressor elements, stressor elements embedded in source and drain regions, and stress liner elements in accordance with examples of the present disclosure;

FIGS. 4B and 4C are respective cross-sectional views of the semiconductor device of FIG. 4A;

FIG. 4D is a flow diagram of a method of forming the semiconductor device with the shallow trench isolation stressor elements, the stressor elements embedded in the source and drain regions, and the stress liner elements shown in FIGS. 4A-4C in accordance with examples of the present disclosure;

FIG. 5A is a plan view (or a layout view) of a semiconductor device with shallow trench isolation stressor elements, stressor elements embedded in source and drain regions, and stress liner elements in accordance with examples of the present disclosure;

FIGS. 5B and 5C are respective cross-sectional views of the semiconductor device of FIG. 5A;

FIG. 6A is a plan view (or a layout view) of a semiconductor device with shallow trench isolation stressor elements, stressor elements embedded in source and drain regions, and stress liner elements in accordance with examples of the present disclosure;

FIGS. 6B and 6C are respective cross-sectional views of the semiconductor device of FIG. 6A;

FIGS. 7A and 7B are respective plan views of metallization layers for source and drain regions of a semiconductor device with embedded stressor elements in accordance with examples of the present disclosure; and

FIGS. 8A and 8B are respective plan views of metallization layers for source and drain regions of a semiconductor device with embedded stressor elements in accordance with examples of the present disclosure.

### DETAILED DESCRIPTION

The present disclosure is described with reference to the attached figures. The components in the figures are not drawn to scale. Instead, emphasis is placed on clearly illustrating overall features and principles of the present disclosure. Numerous specific details and relationships are set forth with reference to examples of the figures to provide an understanding of the present disclosure. The figures and examples are not meant to limit the scope of the present disclosure to such examples, and other examples are possible by way of interchanging or modifying at least some of the described or illustrated elements. Moreover, where elements of the present disclosure can be partially or fully implemented using known components, certain portions of such components that facilitate an understanding of the present disclosure are described, and detailed descriptions of other portions of such components are omitted so as not to obscure the present disclosure.

As used herein, terms such as “first” and “second” are used to arbitrarily distinguish between the elements such terms describe. Thus, these terms in the description and in the claims are not intended to indicate temporal or other prioritization of such elements. Moreover, terms such as “front,” “back,” “top,” “bottom,” “over,” “under,” “vertical,” “horizontal,” “lateral,” “down,” “up,” “upper,” “lower,” or the like, are used to refer to relative directions or positions of features in devices in view of the orientation shown in the figures. For example, “upper” or “uppermost” can refer to a feature positioned closer to the top of a page than other features. The terms so used are interchangeable under appropriate circumstances such that the examples and illustrations of the technology described herein are, for example, capable of operation in other orientations than those illustrated or otherwise described herein. In the following discussion and in the claims, the terms “including,” “includes,” “having,” “has,” “with,” or variants thereof are intended to be inclusive in a manner similar to the term “comprising,” and thus should be interpreted to mean, for example, “including, but not limited to. ” Further, in some examples, the terms “about,” “approximately,” or “substantially” preceding a value mean +/−10-20 percent of the stated value. Still further, unless otherwise specified, the ordering of steps in the description and in the claims are not intended to limit sequencing of the performance of steps and thus alternate step sequencing is contemplated as appropriate.

Various structures disclosed herein can be formed using semiconductor process techniques. Layers including a variety of materials can be formed over a substrate (e.g., a semiconductor wafer), for example, using deposition techniques (e.g., chemical vapor deposition, physical vapor deposition, atomic layer deposition, spin coating, plating), thermal process techniques (e.g., oxidation, nitridation, epitaxy), and/or other suitable techniques. Similarly, some portions of the layers can be selectively removed, for example, using etching techniques (e.g., plasma (or dry) etching, wet etching), chemical mechanical planarization, and/or other suitable techniques, some of which may be combined with photolithography steps. The conductivity (or resistivity) of the substrate (or regions of the substrate) can be controlled by doping techniques using various chemical species (which may also be referred to as dopants, dopant atoms, or the like) including, but not limited to, boron, gallium, indium, arsenic, phosphorus, or antimony. Doping may be performed during the initial formation or growth of the substrate (or an epitaxial layer grown on the substrate), by ion-implantation, or other suitable doping techniques.

Drain extended transistors may include drain-extended n-type metal oxide semiconductor (DENMOS) and p-type metal oxide semiconductor (DEPMOS) transistors, as well as p-channel and n-channel laterally diffused metal oxide semiconductor (PLDMOS and NLDMOS) transistors, as well as groups of DENMOS and DEPMOS transistors, referred to as drain extended complementary metal oxide semiconductor (DECMOS) transistors. Linear bipolar complementary metal oxide semiconductor devices (BiCMOS) transistor technologies may also utilize drain extensions. These and other types of transistor devices may have an active area width in the range of about 10 to 50 micrometers (μm).

The Ids-Ioff performance (e.g., ratios between on-state current (Ids) and off-state current (Ioff)) of p-type metal oxide semiconductor (PMOS) transistors, however, may improve with an active area width that is less than 1 μm—e.g., due to shallow trench isolation (STI) region stress in some cases. In some examples, the Ids-Ioff performance may further improve when the PMOS transistors are fabricated on rotated substrates—e.g., as indicated with a notch orientation. For high current drive applications requiring a large device area, multiple active area regions may be used (e.g., connected) in parallel, where each of the active area regions are separated by an STI region. In some examples, the STI region may have a width of about 0.2 μm or greater. Reducing the size of the active area regions (e.g., having area widths of approximately 1 μm or less) to improve transistor performance, however, will result in a significant increase in total device area thus negating the effect of improved transistor performance—e.g., Ids-Ioff performance, Rsp.

Semiconductor devices, including but not limited to stress-enhanced PLDMOS, PMOS and DEPMOS transistors, are described herein which allow for improved transistor performance while reducing overall device area. In some examples, the stress effects may be combined with rotated substrates so as to further improve the transistor performance.

In some examples, PLDMOS transistor performance improves significantly for active area region widths less than or equal to 1 μm due to stress from adjacent STI regions that separate the active area regions. In some examples, the STI regions have a width of about 0.2 μm. The STI regions, however, do not contribute to electrical conduction and may reduce the effective electrical width for active area region widths that are greater than 1 μm and less than or equal to 5 μm. As such, the STI regions may negate the effect of active area width scaling in improving transistor performance for PLDMOS, DEPMOS and other transistors.

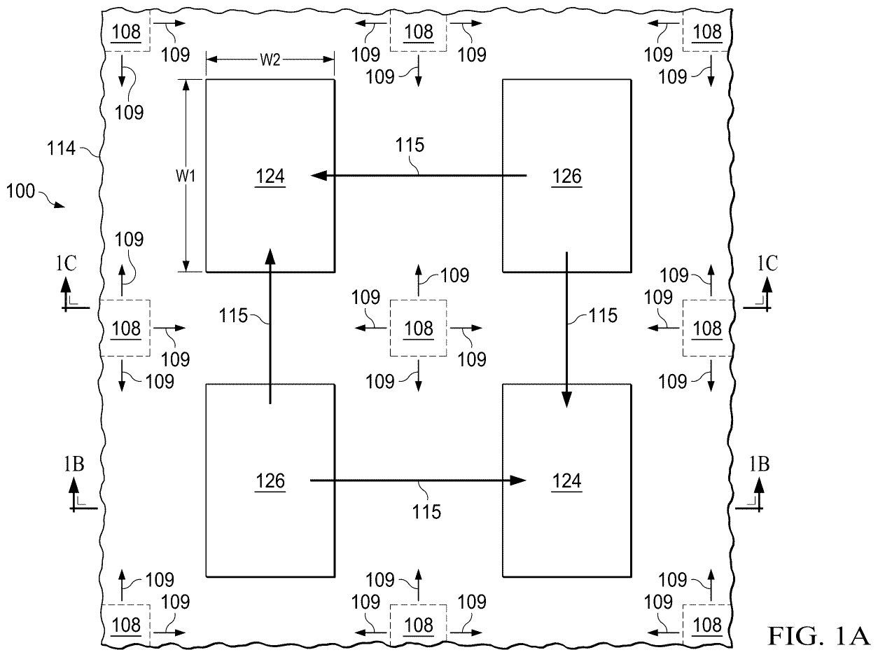

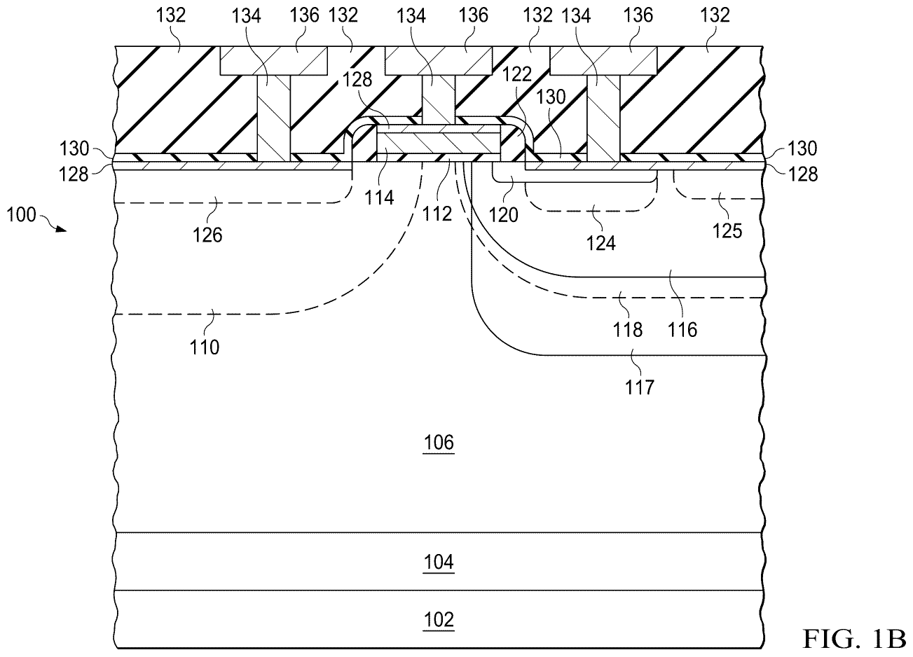

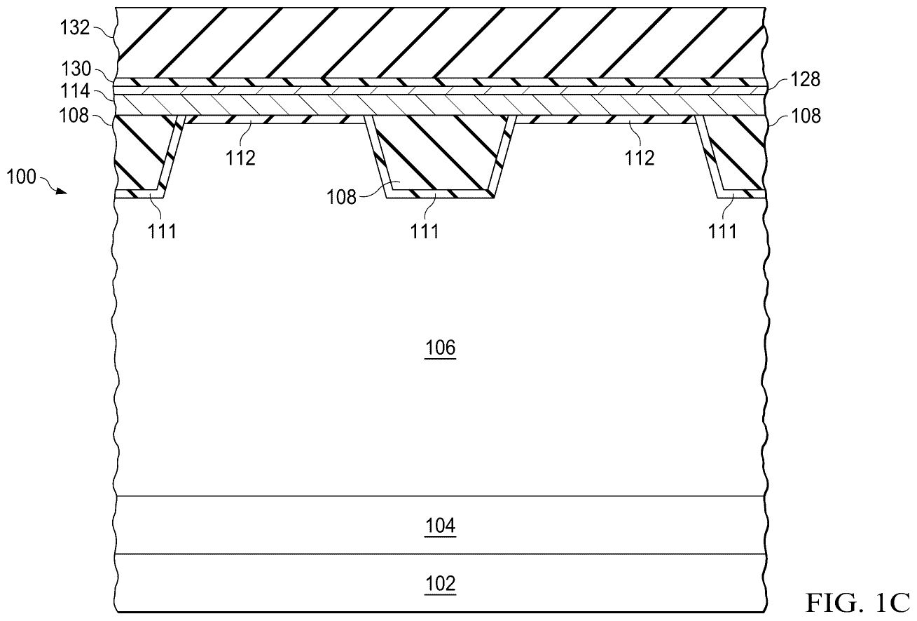

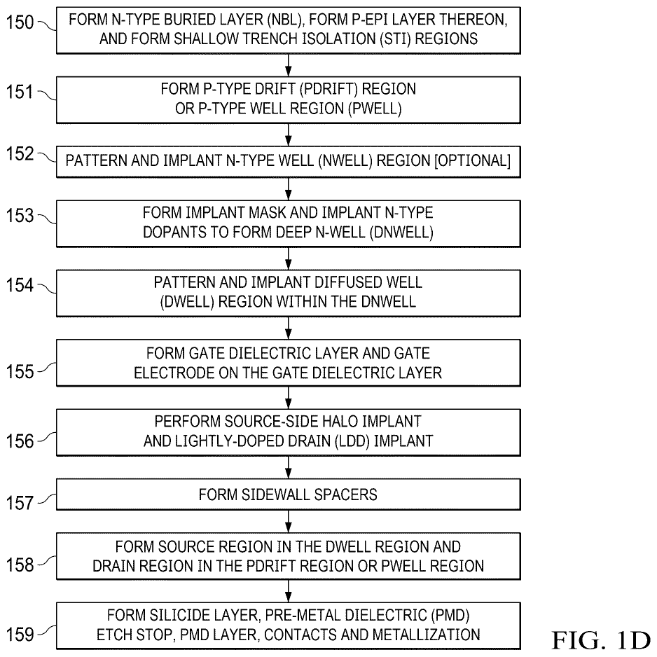

Referring now to FIGS. 1A-1C, a stress-enhanced LDMOS transistor structure 100 with orthogonal or bidirectional current flow is shown. The stress-enhanced LDMOS transistor structure 100 includes a substrate 102, a buried layer 104, an epitaxial layer 106, STI regions 108, a drain drift region 110, a liner dielectric layer 111, a gate dielectric layer 112, a gate electrode 114, a well region 116, a well region 117, a diffusion suppression implant region 118, a shallow well region 120, gate sidewall spacers 122, source regions 124, back gate region 125, drain regions 126, silicide layers 128, a pre-metal dielectric (PMD) etch stop layer 130, a PMD layer 132, contacts 134 and metal interconnects 136.

FIG. 1A shows a plan view (which may also be referred to as a layout view) of the stress-enhanced LDMOS transistor structure 100, while FIGS. 1B and 1C show respective cross-sectional views of the stress-enhanced LDMOS transistor structure 100. As shown in FIG. 1A, the source regions 124 and drain regions 126 are arranged in a grid with two rows and two columns. It should be appreciated, however, that there may be more than two rows and/or more than two columns of source and drain regions arranged in a grid structure in other examples. The particular numbers of source and drain regions (e.g., the size of the grid structure or array) may scale as desired based on the power requirements for the stress-enhanced LDMOS transistor structure 100. The cross-sectional view of FIG. 1B is taken across one of the rows (e.g., across one of the source regions 124 and one of the drain regions 126), while the cross-sectional view of FIG. 1C is taken between the two rows and across a set of the STI regions 108.

The plan view of FIG. 1A illustrates the direction 109 of stress from the STI regions 108. In this example, the STI regions 108 apply compressive stress (e.g., to the channel region between the source regions 124 and the drain regions 126) in both a first direction and a second direction that is orthogonal to the first direction. In the stress-enhanced LDMOS transistor structure 100, current flows in directions 115 from each of the drain regions 126 to each of the source regions 124. The STI regions 108 are arranged adjacent to the source regions 124 and the drain regions 126. While FIG. 1A shows the STI regions 108 spaced apart from the corners of the source regions 124 and the drain regions 126, in other examples the STI regions 108 may be larger and extend to touch corners of the source regions 124 and the drain regions 126.

Each of the source regions 124 and the drain regions 126 may have a unit cell device area defined by widths W1 and W2. The unit cell device area may be scaled to small values of W1 and W2 to enhance stress effects without detrimental impact to total device area and transistor performance (e.g., electrical width). In some examples, the substrate 102 is rotated (e.g., by 45 degrees). For example, the substrate 102 may be formed from a silicon wafer with a {100} crystalline orientation with a first notch orientation, such that the stress-enhanced LDMOS transistor structure 100 (e.g., the direction 115 of current flow) is oriented in the <100> direction. In other examples, the substrate 102 is formed from a silicon wafer with a {100} crystalline orientation with a second notch orientation rotated by 45 degrees in comparison to the first notch orientation, such that the stress-enhanced LDMOS transistor structure 100 (e.g., the direction 115 of current flow) is oriented in the <110> direction. In some examples, an increase in the ratio of the electrical width of the active area is achieved by reducing the window width W2 (or W1), which may result in changing the number of contacts and spacing between the source regions 124, the drain regions 126 and the gate electrode 114.

Although FIG. 1A shows the source regions 124 and the drain regions 126 as being equal in dimension for simplification of illustration of the plan view, the present disclosure is not limited thereto. For example, the dimensions of the source regions 124 and the drain regions 126 may vary as per the LDMOS transistor configuration. Thus, although FIG. 1A shows the sizing of the source regions 124 and the drain regions 126 as being identical, this is not a requirement. Further, one or more of the source/drain region windows (e.g., as shown in FIG. 1A) may be curved.

Referring now to FIG. 1D, a process flow for forming the stress-enhanced LDMOS transistor structure 100 is shown. The process flow begins with step 150, where the substrate 102 is provided with the buried layer 104 and the epitaxial layer 106 formed thereon. The epitaxial layer 106 may be about 15 to 40 μm thick. The process may include forming the buried layer 104 over the substrate 102, and forming the epitaxial layer 106 over the buried layer 104. The substrate 102 and the epitaxial layer 106 are a first conductivity type (e.g., p-type), while the buried layer 104 is a second conductivity type (e.g., n-type, and thus referred to as an n-type buried layer or NBL). The substrate 102 may have a doping level (e.g., of boron) in the range of 1×10¹⁶ to 1×10¹⁹ cm⁻³, and the epitaxial layer 106 may have a doping level (e.g., of boron) in the range of 3×10¹⁴ to 3×10¹⁶ cm⁻³. The substrate 102, the buried layer 104 and the epitaxial layer 106 may be formed of silicon, and may also include other semiconducting materials. The step 150 also includes forming the STI regions 108. Trenches may be formed in the epitaxial layer 106, followed by forming a liner dielectric layer 111 (e.g., silicon dioxide (SiO₂)) on the trench bottoms and sidewalls. Subsequently, a blanket deposition of SiO₂ or another suitable dielectric material fills the trenches, followed by removal of the overburden of the dielectric material that is outside of the trench areas using chemical mechanical planarization (CMP).

In step 151, a region is patterned and implanted with the first conductivity type (e.g., p-type) to form the drain drift region 110 or a p-type well region (PWELL) within exposed pattern areas of the epitaxial layer 106. The drain drift region 110 may be formed by an ion implant process with one or more dopants of the first conductivity type. In some examples, the ion implant includes a boron implant with an energy of 10 to 200 kiloelectronvolts (keV), with a dose in the range of 1×10¹² cm⁻² to 5×10¹³ cm⁻², and with a tilt angle between 0 and 7 degrees, and an indium implant with an energy of between 40 to 150keV, a dose between 1×10¹² cm⁻² to 2×10¹³ cm⁻² and a tilt angle between 0 and 7 degrees.

In step 152, the well region 117 may be formed using a suitably patterned implant mask. It should be noted that the well region 117 is optional, and may be omitted in some examples. The well region 117 may have the second conductivity type (e.g., n-type). The well region 117, if present, may have a depth into the epitaxial layer 106 which is similar to that of the drain drift region 110, though the well region 117 may also extend as far as the buried layer 104. In some examples, the well region 117 is formed using an implant of arsenic with a dose of about 7.0×10¹¹ cm⁻² at about 40 keV, followed by an implant of phosphorus with a dose of about 4.0×10¹² cm⁻² at about 260 keV, following by an implant of phosphorus with a dose of about 2.5×10¹³ cm⁻² at about 390 keV.

In step 153, photolithographic patterning is used to define an opening for an ion implant mask for a first deep well (DNWELL) ion implant. The DNWELL ion implant uses a dopant of the second conductivity type (e.g., n-type). The dopant of the second conductivity type is implanted into the epitaxial layer 106 to form the well region 116 (also referred to as a DNWELL region). The DNWELL ion implant may include one or more n-type DNWELL ion implants at different energies, such as a phosphorus implant with an energy of 25 to 100 keV, at a dose in a range between about 5×10¹² cm⁻² and about 1×10¹⁴ cm⁻² with a tilt angle in a range between about 2 degrees and 30 degrees. The phosphorus implant may be used in combination with an arsenic implant with an energy in a range between about 30 and 100 keV, at a dose in a range between about 2×10¹² cm⁻² and about 2×10¹⁴ cm⁻² with a tilt angle in a range between about 2 to 30 degrees. The well region 116 provides a body region of the stress-enhanced LDMOS transistor structure 100.

Before the ion implant mask for the DNWELL ion implant is removed, a series of diffusion suppression implants may be made to create a diffusion suppression implant region 118 in the epitaxial layer 106. The diffusion suppression implant region 118 may include a diffusion suppression species that includes at least one of carbon, nitrogen and fluorine, and is at least partially spatially coincident with the well region 116. The carbon may enable a more abrupt junction between the well region 116 and the epitaxial layer 106, resulting in lower source-to-drain resistance (Rsd). The nitrogen may limit penetration of boron into the gate electrode, resulting in higher channel mobility and improved performance. The fluorine and carbon are expected to fill interstitials in the semiconductor material of the well region 116, thus limiting boron diffusion. The carbon implant may have an energy between 3 keV and 20 keV, a dose between 2×10¹³ cm⁻² to 1×10¹⁵ cm⁻² and an implant angle between 2 degrees and 45 degrees. The nitrogen implant may have an energy between 5 keV and 30 keV, a dose between 2×10¹³ cm⁻² to 2×10¹⁵ cm⁻² and an implant angle between 2 degrees and 45 degrees. The fluorine implant may have an energy between 2 keV and 20 keV, a dose between 5×10¹³ cm⁻² to 4×10¹⁵ cm⁻² and an implant angle between 2 degrees and 45 degrees. The implant parameters disclosed here are presented by way of example and can also be made in multiple steps. The fluorine may be implanted as boron difluoride (BF₂) to reduce an implant depth and reduce channeling.

The use of one or more of carbon, nitrogen, and fluorine diffusion suppression species is expected to improve the transistor operating characteristics with respect to at least one of Rsd, Ioff, and Vt. In some cases the use of all of carbon, nitrogen, and fluorine may provide especially favorable improvement of these transistor operating characteristics. An amorphizing species, such as indium or germanium, may be implanted before the carbon, nitrogen, and/or fluorine to amorphize the epitaxial layer 106 at the top surface. Such an amorphizing implant may advantageously reduce channeling by the carbon, nitrogen, and/or fluorine, resulting in more uniform placement of these species.

In step 154, the shallow well region 120 is formed. The shallow well region 120, which may be referred to as a DWELL, is formed by a DWELL ion implant that includes boron, by way of example, followed by a thermal drive. The shallow well region 120 is optional, and may provide a channel limit region defining a boundary between a channel region and a source extension. The DWELL ion implant (e.g., for forming the shallow well region 120) and the DNWELL ion implant (e.g., for forming the well region 116) may be performed in either order. In some examples, a boron implant with an energy between about 4 to 30 keV, a dose between 4×10¹⁴ cm⁻² to 1.2×10¹⁵ cm⁻² and an implant angle between 0 to 15 degrees may be used to form the shallow well region 120.

In step 155, material for the gate dielectric layer 112 is formed. The gate dielectric layer 112 may be formed of SiO₂ and have a thickness in the range of about 3 nanometers (nm). The gate dielectric layer 112 may alternately be formed of silicon oxynitride (SiON), and may have a thickness less than 3 nm. The material for the gate dielectric layer 112 may be formed using a high temperature furnace operation or a rapid thermal process. After deposition of the gate dielectric layer 112, material for the gate electrode 114 is formed on the gate dielectric layer 112. The material for the gate electrode 114 may be formed using a suitable chemical vapor deposition (CVD) precursor. The gate electrode 114 may be polycrystalline silicon, a metal gate, a fully silicided (FUSI) gate, or a replacement gate electrode. After the materials for the gate dielectric layer 112 and the gate electrode 114 are formed, photolithographic patterning and plasma etch processing are used to define the gate electrode 114 and the gate dielectric layer 112. As shown in FIG. 1B, the gate dielectric layer 112 and the gate electrode 114 extend partway over the drain drift region 110.

In step 156, an optional halo or pocket implant and a lightly-doped drain (LDD) implant may be performed, again using an ion implant mask. These optional steps are performed to form DENMOS and DEPMOS devices. For LDMOS devices, the halo and LDD implants may be omitted. The halo implant may include one or both of phosphorus and arsenic. The phosphorous may be implanted using a dose in a range between about 1×10¹³ cm⁻² and 1.5×10¹⁴ cm², with an energy in a range between about 30 to 60keV and an implant angle in a range between about 0 to 45 degrees. The arsenic may be implanted using a dose in a range between about 1×10¹³ cm⁻² and 1×10¹⁴ cm⁻², with an energy in a range between about 50 to 100 keV, and an implant angle in a range between about 0 to 45 degrees. These implant conditions result in a retrograde dopant distribution, e.g., having a peak dopant concentration below the surface of the epitaxial layer 106. The presence of this dopant distribution is expected to lower surface doping and/or increase carrier mobility in the well region 116. These effects are further expected to reduce the resistance figure of merit (FOM) of the transistor by 5-10% relative to an otherwise identical device lacking the halo implant. The LDD implant uses arsenic for DENMOS and BF₂ for DEPMOS. For LDMOS devices, a DWELL implant is used in lieu of the halo and LDD implants, as the DWELL implant is a dedicated implant which includes both halo and LDD implants.

In step 157, the gate sidewall spacers 122 are formed on the gate electrode 114. The gate sidewall spacers 122 may be formed by depositing a silicon oxide (SiOₓ) layer and a silicon nitride (SiN) layer over the entire wafer surface. After the deposition of the SiOₓ layer and the SiN layer, an anisotropic plasma etch process is used to remove the SiOₓ layer and the SiN layer from horizontal areas of the wafer surface, leaving the SiOₓ layer and the SiN layer on vertical areas to provide the gate sidewall spacers 122. In some examples, a SiN layer may be deposited across the surface of the wafer and etched to form nitride-only gate sidewall spacers 122 on the gate electrode 114.

In step 158, after formation of the gate sidewall spacers 122, the source regions 124 and the drain regions 126 are formed by ion implantation. To form the source regions 124 and the drain regions 126, a series of patterning and ion implantation steps are used to form the source regions 124 in the well region 116, and to form the drain regions 126 in the drain drift region 110 or the PWELL region. The source regions 124 may use ion implant conditions including BF₂ or boron as the source implant species. BF₂ may be implanted with an energy in a range between about 5 to 25 keV, a dose in a range between about 1×10¹⁵ cm⁻² and about 3×10¹⁵ cm⁻² and an implant angle in a range between about 2 to 30 degrees. Boron may be implanted with an energy in a range between about 2 to 20 keV, a dose in a range between 1×10¹⁵ cm⁻² and about 3×10¹⁵ cm⁻² and an implant angle in a range between about 2 to 30 degrees.

The back gate region 125 (e.g., to provide a contact to a body region) is also implanted, which is electrically connected to the source regions 124 through the silicide layer 128. The back gate region 125 can be formed within the well region 116 by performing an implant step introducing n-type dopants (e.g., phosphorus, arsenic) to a dose in a range between 1×10¹⁵ cm⁻² and about 3×10¹⁵ cm⁻². The drain regions 126 may use ion implant conditions including a boron implant with an energy in a range between about 3 to 10 keV, a dose in a range between about 1×10¹⁵ cm⁻² and about 3×10¹⁵ cm⁻² and an implant angle of about zero degrees. The drain regions 126 (and the source region 124) make use of the edge of the gate sidewall spacers 122 for self-alignment. The drain regions 126 contain an average dopant density at least twice that of the drain drift region 110.

In step 159, after the source regions 124 and the drain regions 126 are formed, the silicide layer 128 is formed on exposed silicon and polysilicon regions, followed by deposition of the PMD etch stop layer 130, deposition of the PMD layer 132, formation of the contacts 134, and formation of the metal interconnects 136. The silicide layer 128, which may be referred to as a metal silicide layer, may be formed by deposition of a layer of a metal such as titanium or nickel, which is then heated to form a metal silicide in areas where the metal contacts the epitaxial layer 106 and the gate electrode 114. After the formation of the silicide, the unreacted metal is removed via a wet etch process leaving the silicide layer 128 in the exposed silicon and polysilicon regions. The PMD etch stop layer 130 may be SiN or SiON deposited via a CVD process. The PMD layer 132 may be an oxide deposited using CVD, and may be doped with phosphorus or phosphorus and boron, where the dopants serve as gettering sites for mobile ions. The contacts 134 are formed using a pattern and etch process to form contact holes to the underlying layers, the contact holes generally being filled with a metal such as tungsten. The metal interconnects 136 are formed after the contacts 134 are formed.

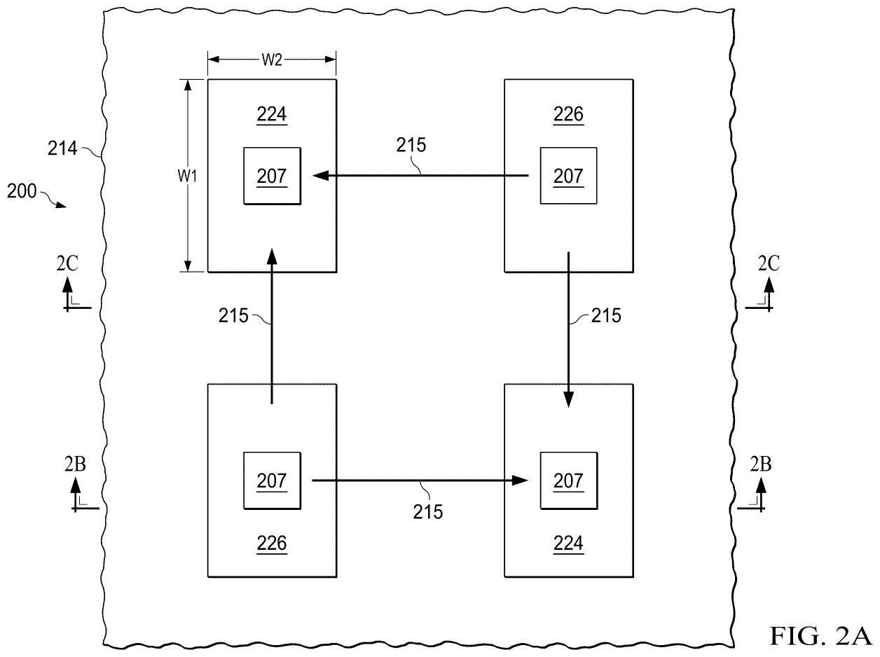

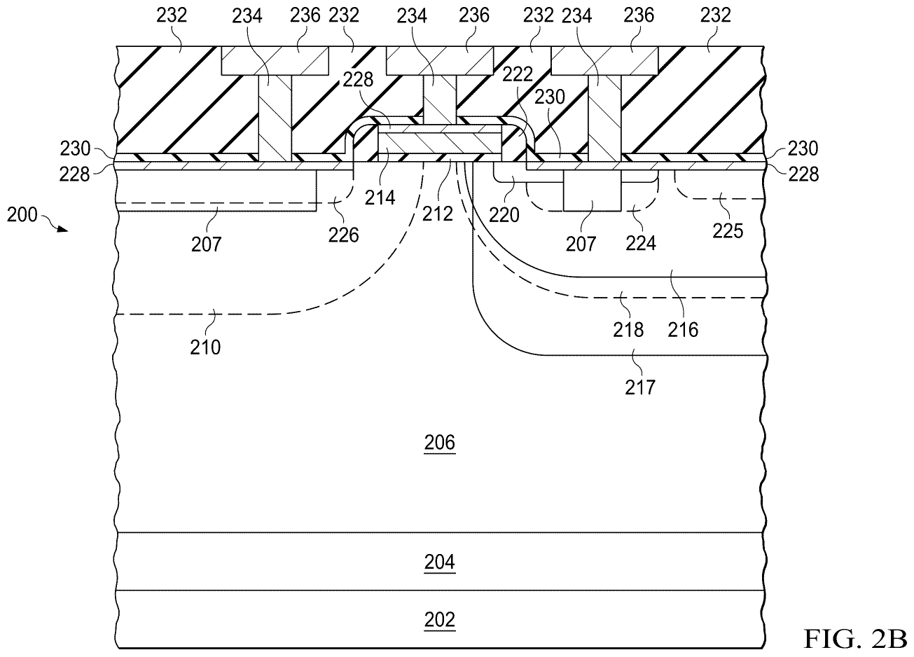

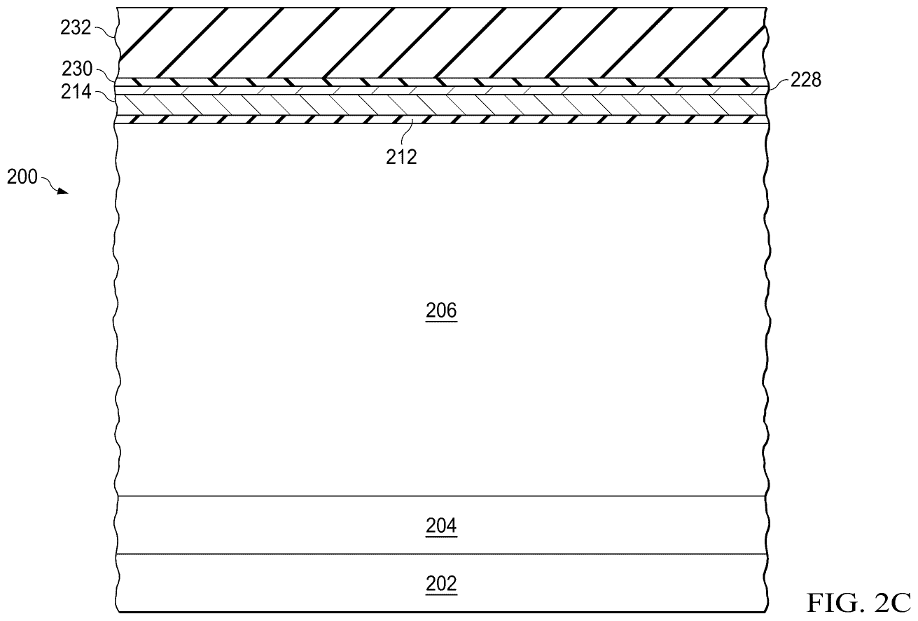

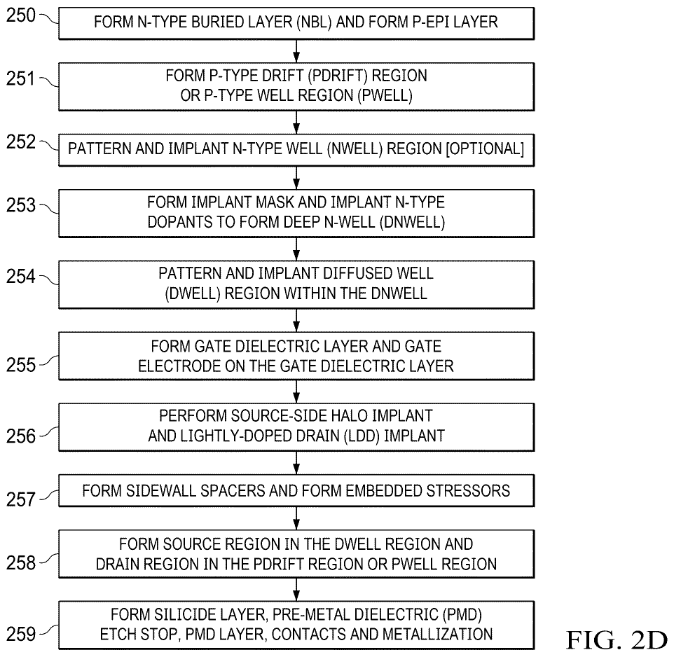

Referring now to FIGS. 2A-2C, another stress-enhanced LDMOS transistor structure 200 with orthogonal or bidirectional current flow is shown. Where the stress-enhanced LDMOS transistor structure 100 utilizes the STI regions 108 as stressors, the stress-enhanced LDMOS transistor structure 200 utilizes stressor elements which are embedded in source/drain regions. The stress-enhanced LDMOS transistor structure 200 includes a substrate 202, a buried layer 204, an epitaxial layer 206, source/drain embedded stressor elements 207, a drain drift region 210, a gate dielectric layer 212, a gate electrode 214, a well region 216, a well region 217, a diffusion suppression implant region 218, a shallow well region 220, gate sidewall spacers 222, source regions 224, back gate region 225, drain regions 226, silicide layers 228, a PMD etch stop layer 230, a PMD layer 232, contacts 234 and metal interconnects 236.

FIG. 2A shows a plan view of the stress-enhanced LDMOS transistor structure 200, while FIGS. 2B and 2C show respective cross-sectional views of the stress-enhanced LDMOS transistor structure 200. As shown in FIG. 2A, the source regions 224 and drain regions 226 are arranged in a grid with two rows and two columns. It should be appreciated, however, that there may be more than two rows and/or more than two columns of source and drain regions arranged in a grid structure in other examples. The particular numbers of source and drain regions (e.g., the size of the grid structure or array) may scale as desired based on the power requirements for the stress-enhanced LDMOS transistor structure 200. The cross-sectional view of FIG. 2B is taken across one of the rows (e.g., across one the source regions 224 and one of the drain regions 226), while the cross-sectional view of FIG. 2C is taken between the two rows.

In the stress-enhanced LDMOS transistor structure 200, current flows in directions 215 from each of the drain regions 226 to each of the source regions 224. The source/drain embedded stressor elements 207 may apply compressive (or tensile) stress outwardly (similar to the direction 109 of compressive stress from the STI regions 108 in the stress-enhanced LDMOS transistor structure 100). Each of the source regions 224 and the drain regions 226 may have a unit cell device area defined by widths W1 and W2. The unit cell device area may be scaled to small values of W1 and W2 to enhance stress without detrimental impact to total device area and electrical width. In some examples, the substrate 202 is rotated (e.g., by 45 degrees). In some examples, the substrate 202 is formed from a silicon wafer with a {100} crystalline orientation, with the stress-enhanced LDMOS transistor structure 200 (e.g., the direction 215 of current flow) being oriented in the <100> direction. In other examples, the substrate 202 is formed from a silicon wafer with a {100} crystalline orientation, with the stress-enhanced LDMOS transistor structure 200 (e.g., the direction 215 of current flow) being oriented in the <110> direction—e.g., by rotating the substrate by 45 degrees.

Although FIG. 2A shows the source regions 224 and the drain regions 226 as being equal in dimension for simplification of illustration of the plan view, the present disclosure is not limited thereto. For example, the dimensions of the source regions 224 and the drain regions 226 may vary as per the LDMOS transistor configuration. Thus, although FIG. 2A shows the sizing of the source regions 224 and the drain regions 226 as being identical, this is not a requirement. Further, one or more of the source/drain region windows (as shown in FIG. 2A) may be curved.

Referring now to FIG. 2D, a process flow for forming the stress-enhanced LDMOS transistor structure 200 is shown. The process flow begins with step 250, where the substrate 202 is provided with the buried layer 204 and the epitaxial layer 206 formed thereon in a manner similar to that described above with respect to the substrate 102, the buried layer 104 and the epitaxial layer 106. In step 251, the drain drift region 210 or PWELL region is formed using processing similar to that described above with respect to formation of the drain drift region 110. In step 252, the well region 217 is formed using processing similar to that described above with respect to formation of the well region 117. The well region 217, like the well region 117, is optional and may be omitted in some examples. In step 253, the well region 216 and the diffusion suppression implant region 218 are formed using processing similar to that described above with respect to formation of the well region 116 and the diffusion suppression implant region 118. In step 254, the shallow well region 220 is formed using processing similar to that described above with respect to formation of the shallow well region 120. In step 255, the gate dielectric layer 212 and the gate electrode 214 are formed using processing similar to that described above with respect to formation of the gate dielectric layer 112 and the gate electrode 114. In step 256, an optional halo or pocket implant and LDD implant may be performed in a manner similar to that described above with respect to step 156.

In step 257, the gate sidewall spacers 222 are formed using processing similar to that described above with respect to formation of the gate sidewall spacers 122. Step 257 also includes formation of the source/drain embedded stressor elements 207. The source/drain embedded stressor elements 207 may be formed by etching into the substrate (the epitaxial layer 206) to form cavities where the source/drain embedded stressor elements 207 are to be formed, followed by filling (e.g., by epitaxial growth) a stressor material (e.g., SiGe or SiC) within the cavities. In step 258, the source regions 224, the back gate region 225 and the drain regions 226 are formed using processing similar to that described above with respect to formation of the source regions 124, the back gate region 125 and the drain regions 126. In step 259, the silicide layer 228, the PMD etch stop layer 230, the PMD layer 232, the contacts 234 and the metal interconnects 236 are formed using processing similar to that described above with respect to formation of the silicide layer 128, the PMD etch stop layer 130, the PMD layer 132, the contacts 134 and the metal interconnects 136.

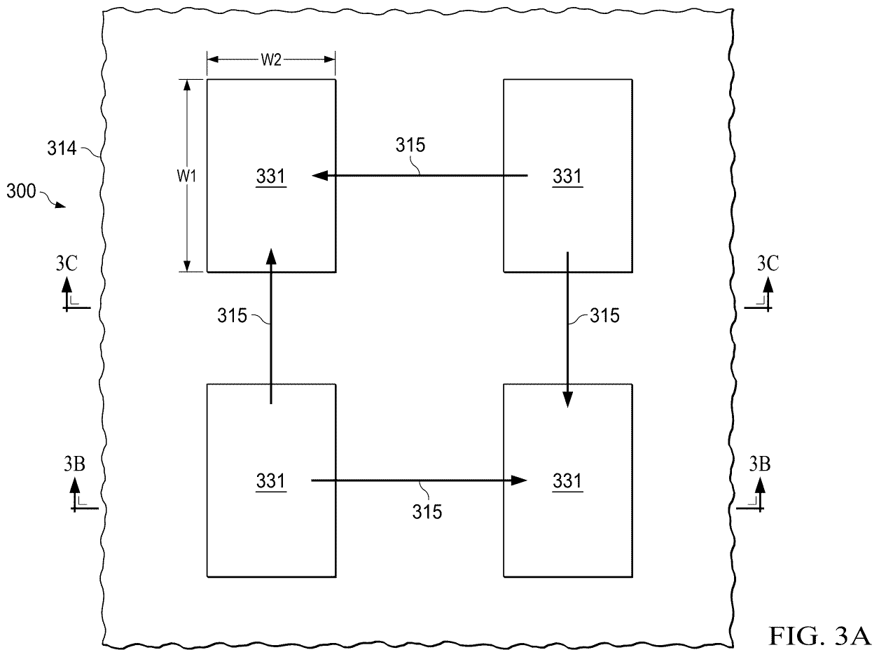

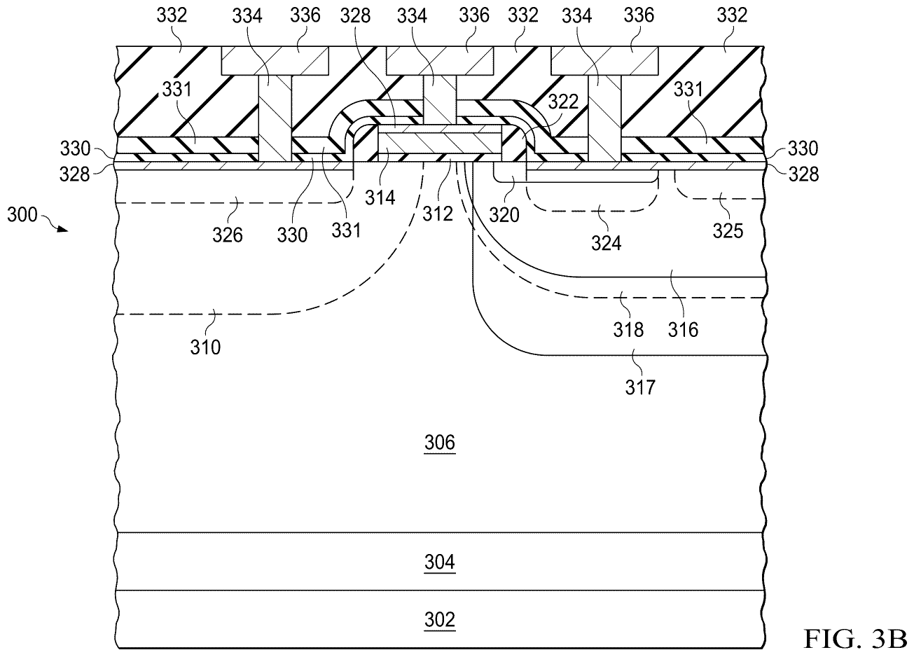

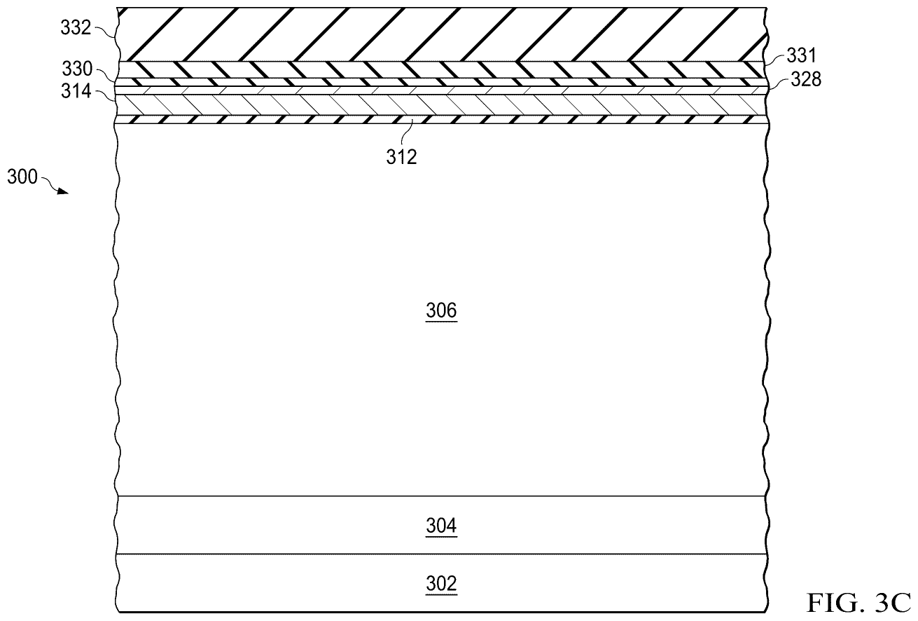

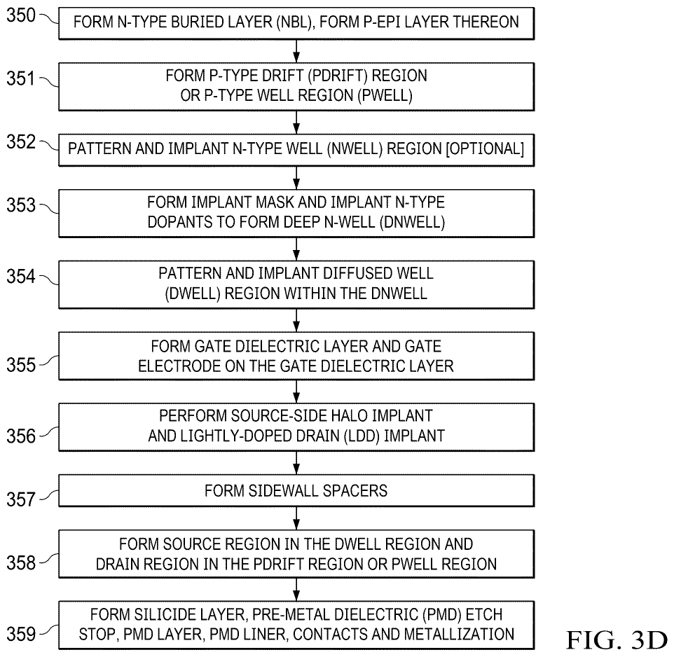

Referring now to FIGS. 3A-3C, another stress-enhanced LDMOS transistor structure 300 with orthogonal or bidirectional current flow is shown. Where the stress-enhanced LDMOS transistor structure 100 utilizes the STI regions 108 as stressors and the stress-enhanced LDMOS transistor structure 200 utilizes stressor elements which are embedded in source/drain regions, the stress-enhanced LDMOS transistor structure 300 utilizes a dielectric stress layer or a dielectric stress liner (e.g., a PMD liner) as a stressor element. The stress-enhanced LDMOS transistor structure 300 includes a substrate 302, a buried layer 304, an epitaxial layer 306, a drain drift region 310, a gate dielectric layer 312, a gate electrode 314, a well region 316, a well region 317, a diffusion suppression implant region 318, a shallow well region 320, gate sidewall spacers 322, source regions 324, back gate region 325, drain regions 326, silicide layers 328, a PMD etch stop layer 330, a dielectric stress liner 331 acting as a stressor element, a PMD layer 332, contacts 334 and metal interconnects 336. In some examples, the PMD etch stop layer 330 may include the dielectric stress liner 331 or vice versa.

FIG. 3A shows a plan view of the stress-enhanced LDMOS transistor structure 300, while FIGS. 3B and 3C show respective cross-sectional views of the stress-enhanced LDMOS transistor structure 300. The source regions 324 and drain regions 326 are arranged in a grid with two rows and two columns. It should be appreciated, however, that there may be more than two rows and/or more than two columns of source and drain regions arranged in a grid structure in other examples. The particular numbers of source and drain regions (e.g., the size of the grid structure or array) may scale as desired based on the power requirements for the stress-enhanced LDMOS transistor structure 300. The cross-sectional view of FIG. 3B is taken across one of the rows (e.g., across one of the source regions 324 and one of the drain regions 326), while the cross-sectional view of FIG. 3C is taken between the two rows.

In the stress-enhanced LDMOS transistor structure 300, current flows in directions 315 from each of the drain regions 326 to each of the source regions 324. The dielectric stress liner 331 may apply compressive or tensile stress - e.g., to the substrate where the current flows. In some examples, the dielectric stress liner 331 is a single liner which applies tensile or compressive stress for both n-and p-type source/drain regions. In other examples, the dielectric stress liner 331 is a dual liner which applies tensile stress for n-type transistors and compressive stress for p-type transistors, respectively. Each of the source regions 324 and the drain regions 326 may have a unit cell device area defined by widths W1 and W2. The unit cell device area may be scaled to small values of W1 and W2 to enhance stress effects without detrimental impact to total device area and transistor performance (e.g., electrical width). In some examples, the substrate 302 is rotated (e.g., by 45 degrees). In some examples, the substrate 302 is formed from a silicon wafer with a crystalline orientation, with the stress-enhanced LDMOS transistor structure 300 (e.g., the direction 315 of current flow) being oriented in the <100> direction. In other examples, the substrate 302 is formed from a silicon wafer with a {100} crystalline orientation, with the stress-enhanced LDMOS transistor structure 300 (e.g., the direction 315 of current flow) being oriented in the <110> direction—e.g., by rotating the substrate by 45 degrees.

Although FIG. 3A shows the source regions 324 and the drain regions 326 as being equal in dimension for simplification of illustration of the plan view, the present disclosure is not limited thereto. For example, the dimensions of the source regions 324 and the drain regions 326 may vary as per the LDMOS transistor configuration. Thus, although FIG. 3A shows the sizing of the source regions 324 and the drain regions 326 as being identical, this is not a requirement. Further, one or more of the source/drain region windows (e.g., as shown in FIG. 3A) may be curved.

Referring now to FIG. 3D, a process flow for forming the stress-enhanced LDMOS transistor structure 300 is shown. The process flow begins with step 350, where the substrate 302 is provided with the buried layer 304 and the epitaxial layer 306 formed thereon in a manner similar to that described above with respect to the substrate 102, the buried layer 104 and the epitaxial layer 106. In step 351, the drain drift region 310 or PWELL region is formed using processing similar to that described above with respect to formation of the drain drift region 110. In step 352, the well region 317 is formed using processing similar to that described above with respect to formation of the well region 117. The well region 317, like the well region 117, is optional and may be omitted in some examples. In step 353, the well region 316 and diffusion suppression implant region 318 are formed using processing similar to that described above with respect to formation of the well region 116 and the diffusion suppression implant region 118.

In step 354, the shallow well region 320 is formed using processing similar to that described above with respect to formation of the shallow well region 120. In step 355, the gate dielectric layer 312 and the gate electrode 314 are formed using processing similar to that described above with respect to formation of the gate dielectric layer 112 and the gate electrode 114. In step 356, an optional halo or pocket implant and LDD implant may be performed in a manner similar to that described above with respect to step 156. In step 357, the gate sidewall spacers 322 are formed using processing similar to that described above with respect to formation of the gate sidewall spacers 122. In step 358, the source regions 324, the back gate region 325 and the drain regions 326 are formed using processing similar to that described above with respect to formation of the source regions 124, the back gate region 125 and the drain regions 126.

In step 359, the silicide layer 328 and the PMD etch stop layer 330 are formed using processing similar to that described above with respect to formation of the silicide layer 128 and the PMD etch stop layer 130. Prior to formation of the PMD layer 332, the dielectric stress liner 331 is formed. The dielectric stress liner 331 may be formed using one or a series of deposition processes for single or dual dielectric stress liner 331 arrangements. For dual dielectric stress liner 331 arrangements, different areas of the structure may be masked during deposition of the dielectric stress liners for the n-type and p-type transistors in the desired regions in some examples. In other examples, a first stress liner (e.g., a compressive stress liner) is deposited and a portion thereof is removed in areas (e.g., n-channel transistor regions) where a second stress liner will be formed. The second stress liner (e.g., a tensile stress liner) is then deposited. The second stress liner may remain above the first stress liner, or may be removed in areas where the first stress liner is formed. The PMD layer 332 is then formed over the dielectric stress liner 331, followed by formation of the contacts 334 and the metal interconnects 336 using processing similar to that described above with respect to formation of the PMD layer 132, the contacts 134 and the metal interconnects 136.

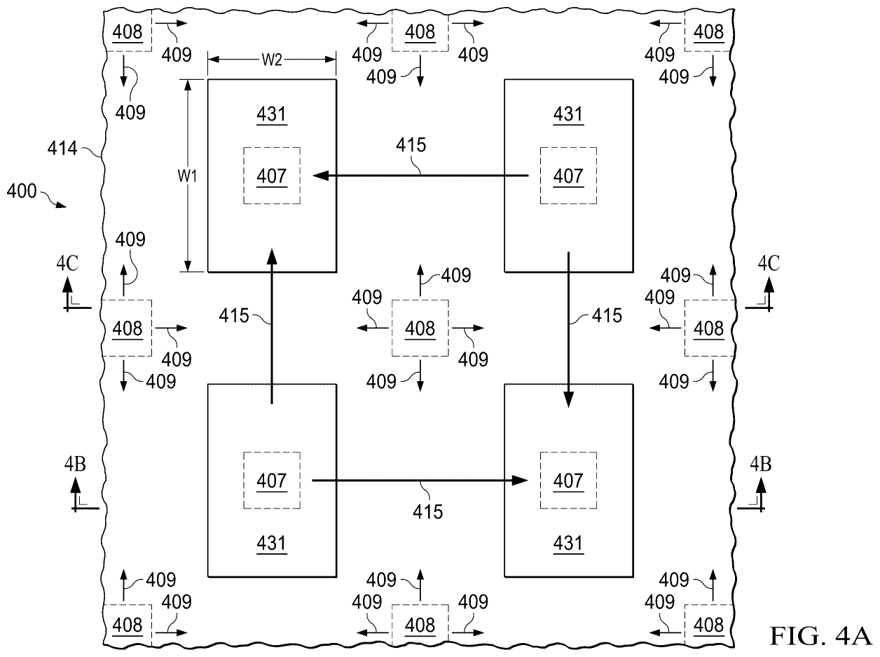

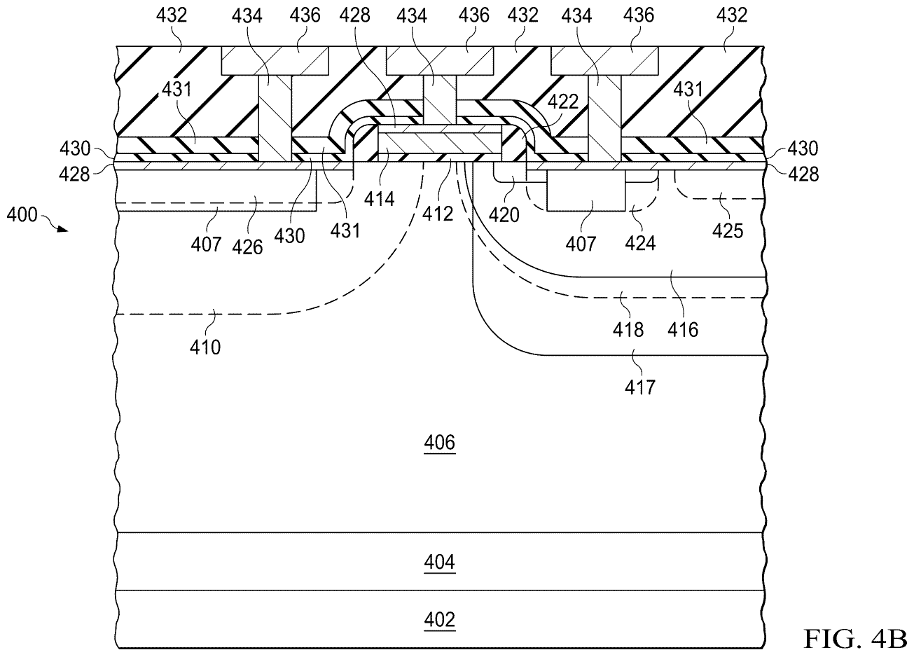

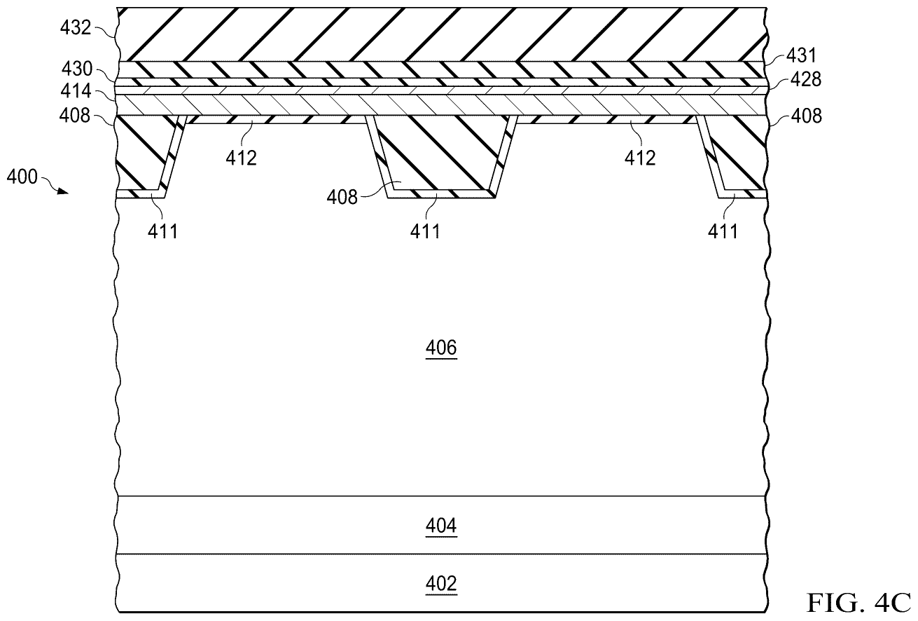

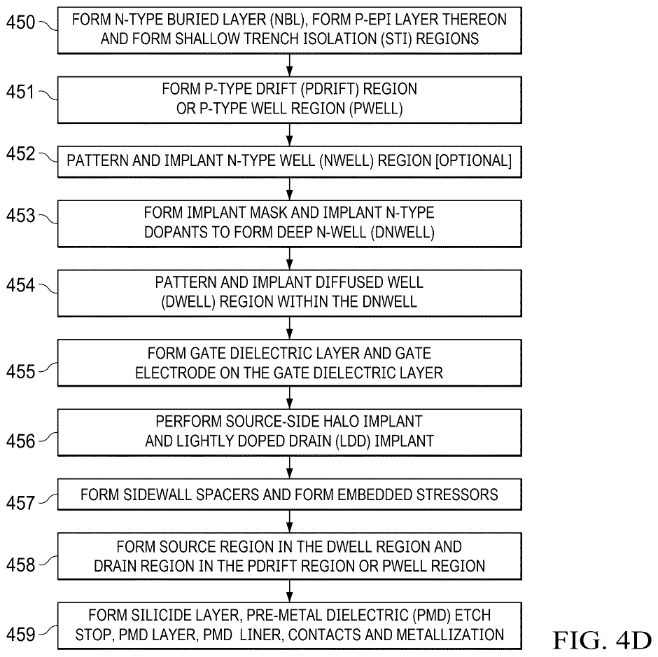

Referring now to FIGS. 4A-4C, another stress-enhanced LDMOS transistor structure 400 with orthogonal or bidirectional current flow is shown is shown. The stress-enhanced LDMOS transistor structure 400 utilizes a combination of stressor elements including STI region stressor elements, source/drain region embedded stressor elements, and dielectric stress liner elements.

The stress-enhanced LDMOS transistor structure 400 includes a substrate 402, a buried layer 404, an epitaxial layer 406, source/drain embedded stressor elements 407, STI regions 408, a drain drift region 410, a liner dielectric layer 411, a gate dielectric layer 412, a gate electrode 414, a well region 416, a well region 417, a diffusion suppression implant region 418, a shallow well region 420, gate sidewall spacers 422, source regions 424, back gate region 425, drain regions 426, silicide layers 428, a PMD etch stop layer 430, a dielectric stress liner 431 acting as a stressor element, a PMD layer 432, contacts 434 and metal interconnects 436.

FIG. 4A shows a plan view of the stress-enhanced LDMOS transistor structure 400, while FIGS. 4B and 4C show cross-sectional views of the stress-enhanced LDMOS transistor structure 400. The source regions 424 and drain regions 426 are arranged in a grid with two rows and two columns. It should be appreciated, however, that there may be more than two rows and/or more than two columns of source and drain regions arranged in a grid structure in other examples. The particular numbers of source and drain regions (e.g., the size of the grid structure or array) may scale as desired based on the power requirements for the stress-enhanced LDMOS transistor structure 400. The cross-sectional view of FIG. 4B is taken across one of the rows (e.g., across one the source regions 424 and one of the drain regions 426), while the cross-sectional view of FIG. 4C is taken between the two rows and across a set of the STI regions 408.

In the stress-enhanced LDMOS transistor structure 400, current flows in directions 415 from each of the drain regions 426 to each of the source regions 424. The top cross-sectional view of FIG. 4A illustrates the direction 409 of stress from the STI regions 408 where, in this example, the STI regions 408 apply compressive stress in both a first direction and a second direction that is orthogonal to the first direction. The source/drain embedded stressor elements 407 similarly apply stress (compressive or tensile) outwardly. The dielectric stress liner 431 also applies compressive or tensile stress. In some examples, the dielectric stress liner 431 is a single liner which applies tensile or compressive stress for both n-and p-type transistors. In other examples, the dielectric stress liner 431 is a dual liner which applies tensile stress for n-type transistors and compressive stress for p-type transistors, respectively.

Each of the source regions 424 and the drain regions 426 may have a unit cell device area defined by widths W1 and W2. The unit cell device area may be scaled to small values of W1 and W2 to enhance stress without detrimental impact to total device area and electrical width. In some examples, the substrate 402 is rotated (e.g., by 45 degrees). In some examples, the substrate 402 is formed from a silicon wafer with a {100} crystalline orientation, with the stress-enhanced LDMOS transistor structure 400 (e.g., current flow direction) being oriented in the <100> direction. In other examples, the substrate 402 is formed from a silicon wafer with a {100} crystalline orientation, with the stress-enhanced LDMOS transistor structure 400 (e.g., current flow direction being oriented in the <110> direction.

Although FIG. 4A shows the source regions 424 and the drain regions 426 as being equal in dimension for simplification of illustration of the plan view, the present disclosure is not limited thereto. For example, the dimensions of the source regions 424 and the drain regions 426 may vary as per the LDMOS transistor configuration. Thus, although FIG. 4A shows the sizing of the source regions 424 and the drain regions 426 as being identical, this is not a requirement. Further, one or more of the source/drain region windows (e.g., as shown in FIG. 4A) may be curved.

Referring now to FIG. 4D, a process flow for forming the stress-enhanced LDMOS transistor structure 400 is shown. The process flow begins with step 450, where the substrate 402 is provided with the buried layer 404 and the epitaxial layer 406 formed thereon in a manner similar to that described above with respect to the substrate 102, the buried layer 104 and the epitaxial layer 106. In step 450, the STI regions 408 and the liner dielectric layer 411 are formed using processing similar to that described above with respect to formation of the STI regions 108 and the liner dielectric layer 111. In step 451, the drain drift region 410 or PWELL region is formed using processing similar to that described above with respect to formation of the drain drift region 110. In step 452, the well region 417 is formed using processing similar to that described above with respect to formation of the well region 117. The well region 417, like the well region 117, is optional and may be omitted in some examples. In step 453, the well region 416 and diffusion suppression implant region 418 are formed using processing similar to that described above with respect to formation of the well region 116 and the diffusion suppression implant region 118. In step 454, the shallow well region 420 is formed using processing similar to that described above with respect to formation of the shallow well region 120.In step 455, the gate dielectric layer 412 and the gate electrode 414 are formed using processing similar to that described above with respect to formation of the gate dielectric layer 112 and the gate electrode 114. In step 456, an optional halo or pocket implant and LDD implant may be performed in a manner similar to that described above with respect to step 156.

In step 457, the gate sidewall spacers 422 are formed using processing similar to that described above with respect to formation of the gate sidewall spacers 122. Step 457 also includes formation of the source/drain embedded stressor elements 407 using processing similar to that described above with respect to formation of source/drain embedded stressor elements 207. In step 458, the source regions 424, the back gate region 425 and the drain regions 426 are formed using processing similar to that described above with respect to formation of the source regions 124, the back gate region 125 and the drain regions 126. In step 459, the silicide layer 428 and the PMD etch stop layer 430 are formed using processing similar to that described above with respect to formation of the silicide layer 128 and the PMD etch stop layer 130. Prior to formation of the PMD layer 432, the dielectric stress liner 431 is formed using processing similar to that described above with respect to formation of the dielectric stress liner 331. The PMD layer 432 is then formed over the dielectric stress liner 431, followed by formation of the contacts 434 and the metal interconnects 436 using processing similar to that described above with respect to formation of the PMD layer 132, the contacts 134 and the metal interconnects 136.

It should be noted that while FIGS. 4A-4C shows the stress-enhanced LDMOS transistor structure 400 as including three different types of stressor elements (e.g., the source/drain embedded stressor elements 407, the STI regions 408 and the dielectric stress liner 431), in other examples a stress-enhanced LDMOS transistor structure may utilize any combination of two or more different types of stressor elements, such as the source/drain embedded stressor elements 407 and the STI regions 408 but not the dielectric stress liner 431, the STI regions 408 and the dielectric stress liner 431 but not the source/drain embedded stressor elements 407, or the source/drain embedded stressor elements 407 and the dielectric stress liner 431 but not the STI regions 408. Further, while FIGS. 1A-1C, 2A-2C and 3A-3C show stress-enhanced LDMOS transistor structures 100, 200 and 300, stress-enhanced PMOS or stress-enhanced DEPMOS structures may also be formed.

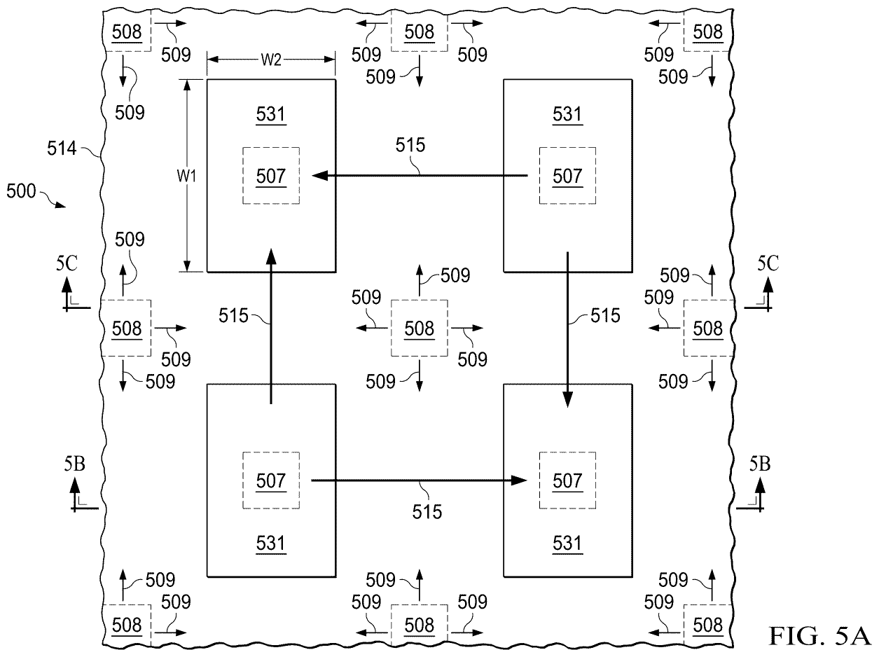

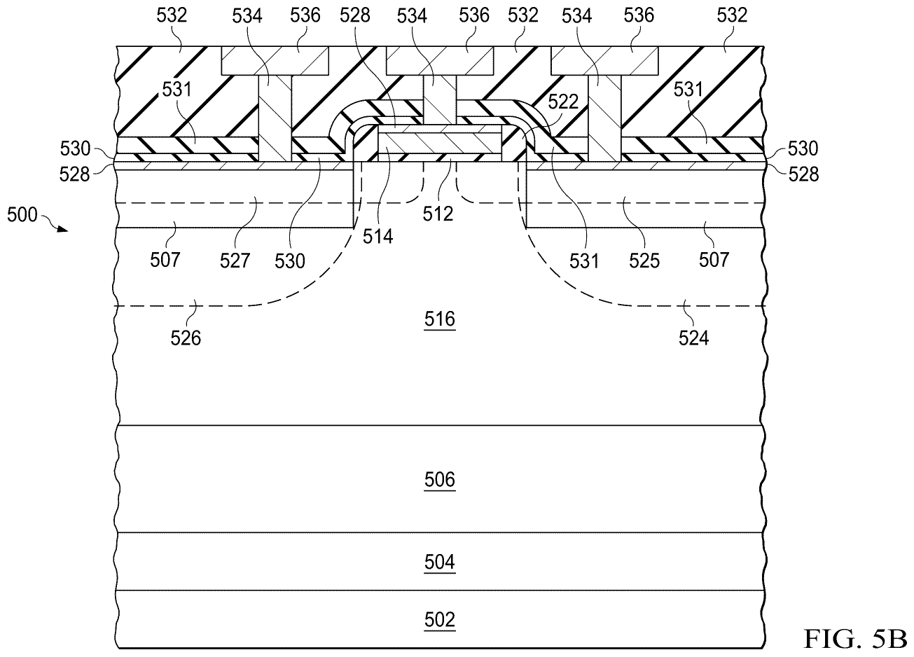

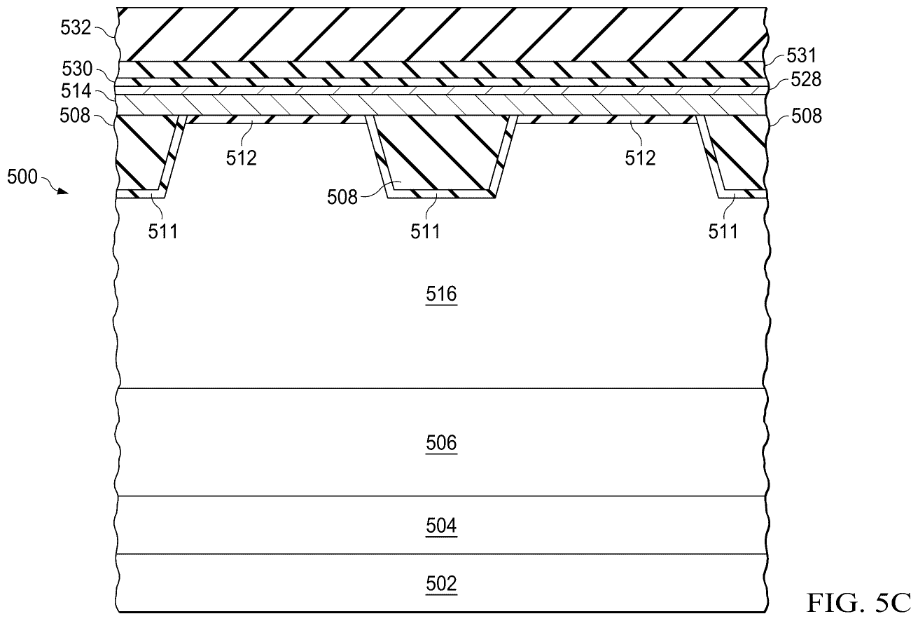

Referring now to FIGS. 5A-5C, a stress-enhanced PMOS transistor structure 500 with orthogonal or bidirectional current flow is shown. The stress-enhanced PMOS transistor structure 500, like the stress-enhanced LDMOS transistor structure 400, utilizes a combination of stressor elements including STI region stressor elements, source/drain embedded stressor elements, and dielectric stress liner elements. The stress-enhanced PMOS transistor structure 500 includes a substrate 502, a buried layer 504, an epitaxial layer 506, source/drain embedded stressor elements 507, STI regions 508, a liner dielectric layer 511, a gate dielectric layer 512, a gate electrode 514, a well region 516, gate sidewall spacers 522, source regions 524, source-side lightly doped drain (LDD) region 525, drain regions 526, drain-side LDD region 527, silicide layers 528, a PMD etch stop layer 530, a dielectric stress liner 531 acting as a stressor element, a PMD layer 532, contacts 534, and metal interconnects 536.

FIG. 5A shows a plan view of the stress-enhanced PMOS transistor structure 500, while FIGS. 5B and 5C show respective cross-sectional views of the stress-enhanced PMOS transistor structure 500. The source regions 524 and the drain regions 526 are arranged in a grid with two rows and two columns. It should be appreciated, however, that there may be more than two rows and/or more than two columns of source and drain regions arranged in a grid structure in other examples. The particular numbers of source and drain regions (e.g., the size of the grid structure or array) may scale as desired based on the power requirements for the stress-enhanced PMOS transistor structure 500. The cross-sectional view of FIG. 5B is taken across one of the rows (e.g., across one the source regions 524 and one of the drain regions 526), while the cross-sectional view of FIG. 5C is taken between the two rows and across a set of the STI regions 508.

In the stress-enhanced PMOS transistor structure 500, current flows in directions 515 from each of the drain regions 526 to each of the source regions 524. The plan view of FIG. 5A illustrates the direction of stress 509 from the STI regions 508 where, in this example, the STI regions 508 apply compressive stress in both a first direction and a second direction that is orthogonal to the first direction. The source/drain embedded stressor elements 507 similarly apply compressive stress outwardly. The dielectric stress liner 531 also applies compressive or tensile stress. In some examples, the dielectric stress liner 531 is a single liner which applies tensile or compressive stress for both n-and p-type source/drain regions. In other examples, the dielectric stress liner 531 is a dual liner which applies tensile stress for n-type transistors and compressive stress for p-type transistors.

Each of the source regions 524 and the drain regions 526 may have a unit cell device area defined by widths W1 and W2. The unit cell device area may be scaled to small values of W1 and W2 to enhance stress effect without detrimental impact to total device area and transistor performance (e.g., electrical width). In some examples, the substrate 502 is rotated (e.g., by 45 degrees). In some examples, the substrate 502 is formed from a silicon wafer with a {100} crystalline orientation, with the stress-enhanced PMOS transistor structure 500 (e.g., the direction 515 of current flow) being oriented in the <100> direction. In other examples, the substrate 502 is formed from a silicon wafer with a {100} crystalline orientation, with the stress-enhanced PMOS transistor structure 500 (e.g., the direction 515 of current flow) being oriented in the <110> direction—e.g., by rotating the substrate by 45 degrees.

The substrate 502, the buried layer 504, the epitaxial layer 506, the STI regions 508, the liner dielectric layer 511, the gate dielectric layer 512, the gate electrode 514, the silicide layers 528, the PMD etch stop layer 530, the PMD layer 532, the contacts 534 and the metal interconnects 536 in the stress-enhanced PMOS transistor structure 500 may be formed using similar processing as that described above with respect to formation of the substrate 102, the buried layer 104, the epitaxial layer 106, the STI regions 108, the liner dielectric layer 111, the gate dielectric layer 112, the gate electrode 114, the silicide layers 128, the PMD etch stop layer 130, the PMD layer 132, the contacts 134 and the metal interconnects 136 in the stress-enhanced LDMOS transistor structure 100. The source/drain embedded stressor elements 507 in the stress-enhanced PMOS transistor structure 500 may be formed using similar processing as that described above with respect to formation of the source/drain embedded stressor elements 207 in the stress-enhanced LDMOS transistor structure 200. The dielectric stress liner 531 in the stress-enhanced PMOS transistor structure 500 may be formed using processing similar to that described above with respect to formation of the dielectric stress liner 331 in the stress-enhanced LDMOS transistor structure 300.

The well region 516, the source regions 524, the source-side LDD region 525, the drain regions 526 and the drain-side LDD region 527 in the stress-enhanced PMOS transistor structure 500 may be formed using suitably patterned implant masks and associated ion implant processes. The substrate 502, the epitaxial layer 506, the source regions 524, the source-side LDD region 525, the drain regions 526 and the drain-side LDD region 527 may be doped to a first conductivity type (e.g., p-type) while the buried layer 504 and the well region 516 are doped to a second conductivity type (e.g., n-type).

It should be noted that while FIGS. 5A-5C shows the stress-enhanced PMOS transistor structure 500 as including three different types of stressor elements (e.g., the source/drain embedded stressor elements 507, the STI regions 508 and the dielectric stress liner 531), in other examples a stress-enhanced PMOS transistor structure may utilize any single type of stressor element, such as one of the source/drain embedded stressor elements 507, the STI regions 508 or the dielectric stress liner 531, or any combination of two or more different types of stressor elements, such as the source/drain embedded stressor elements 507 and the STI regions 508 but not the dielectric stress liner 531, the STI regions 508 and the dielectric stress liner 531 but not the source/drain embedded stressor elements 507, or the source/drain embedded stressor elements 507 and the dielectric stress liner 531 but not the STI regions 508.

Although FIG. 5A shows the source regions 524 and the drain regions 526 as being equal in dimension for simplification of illustration of the plan view, the present disclosure is not limited thereto. For example, the dimensions of the source regions 524 and the drain regions 526 may vary as per the PMOS transistor configuration. Thus, although FIG. 5A shows the sizing of the source regions 524 and the drain regions 526 as being identical, this is not a requirement. Further, one or more of the source/drain region windows (e.g., as shown in FIG. 5A) may be curved.

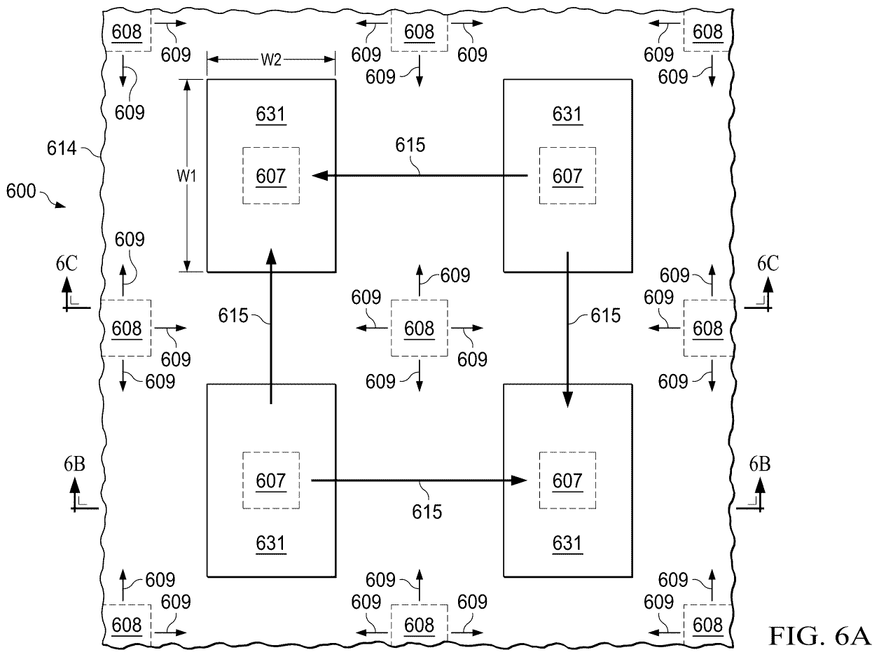

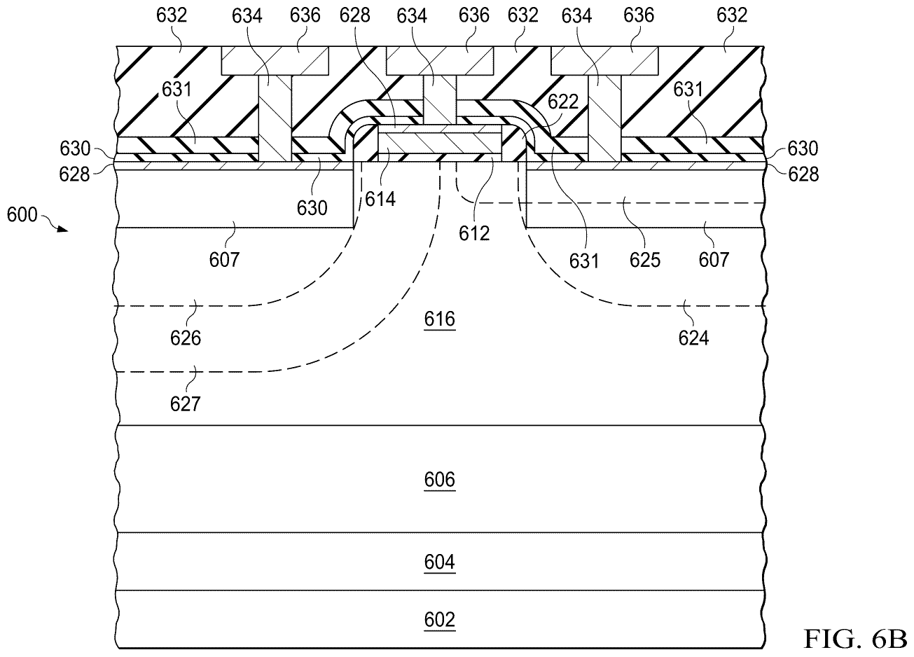

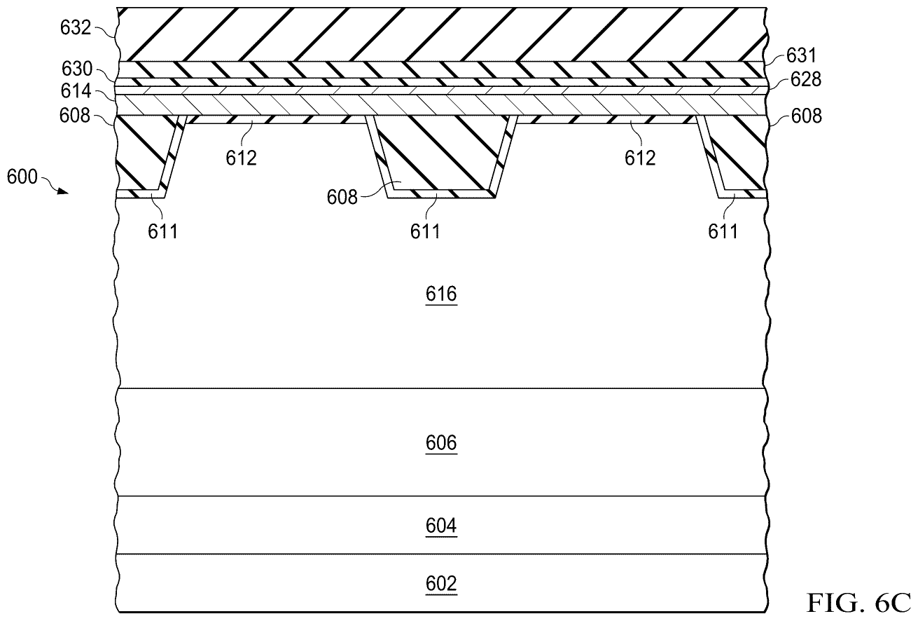

Referring now to FIGS. 6A-6C, a stress-enhanced DEPMOS transistor structure 600 with orthogonal or bidirectional current flow is shown. The stress-enhanced DEPMOS transistor structure 600, like the stress-enhanced LDMOS transistor structure 400 and the stress-enhanced PMOS transistor structure 500, utilizes a combination of stressor elements including STI region stressor elements, source/drain embedded stressor elements, and dielectric stress liner elements. The stress-enhanced DEPMOS transistor structure 600 includes a substrate 602, a buried layer 604, an epitaxial layer 606, source/drain embedded stressor elements 607, STI regions 608, a liner dielectric layer 611, a gate dielectric layer 612, a gate electrode 614, a well region 616, gate sidewall spacers 622, source regions 624, source-side LDD region 625, drain regions 626, a drain drift region 627, silicide layers 628, a PMD etch stop layer 630, a dielectric stress liner 631 acting as a stressor element, a PMD layer 632, contacts 634, and metal interconnects 636.

FIG. 6A shows a plan view of the stress-enhanced DEPMOS transistor structure 600, while FIGS. 6B and 6C show respective cross-sectional views of the stress-enhanced DEPMOS transistor structure 600. As shown in FIG. 6A, the source regions 624 and the drain regions 626 are arranged in a grid with two rows and two columns. It should be appreciated, however, that there may be more than two rows and/or more than two columns of source and drain regions arranged in a grid structure in other examples. The particular numbers of source and drain regions (e.g., the size of the grid structure or array) may scale as desired based on the power requirements for the stress-enhanced DEPMOS transistor structure 600. The cross-sectional view of FIG. 6B is taken across one of the rows (e.g., across one the source regions 624 and one of the drain regions 626), while the cross-sectional view of FIG. 6C is taken between the two rows and across a set of the STI regions 608.

In the stress-enhanced DEPMOS transistor structure 600, current flows in directions 615 (e.g., from each of the drain regions 626 to each of the source regions 624). The plan view of FIG. 6A illustrates the direction of stress 609 from the STI regions 608 where, in this example, the STI regions 608 apply compressive stress in both a first direction and a second direction that is orthogonal to the first direction. The source/drain embedded stressor elements 607 similarly apply stress (compressive) outwardly. The dielectric stress liner 631 also applies compressive or tensile stress. In some examples, the dielectric stress liner 631 is a single liner which applies tensile or compressive stress for both n-and p-type source/drain regions. In other examples, the dielectric stress liner 631 is a dual liner which applies tensile stress for n-type transistors and compressive stress for p-type transistors.

Each of the source regions 624 and the drain regions 626 may have a unit cell device area defined by widths W1 and W2. The unit cell device area may be scaled to small values of W1 and W2 to enhance stress without detrimental impact to total device area and transistor performance (e.g., electrical width). In some examples, the substrate 602 is rotated (e.g., by 45 degrees). In some examples, the substrate 602 is formed from a silicon wafer with a {100} crystalline orientation, with the stress-enhanced DEPMOS transistor structure 600 (e.g., the direction 615 of current flow) being oriented in the <100> direction. In other examples, the substrate 602 is formed from a silicon wafer with a {100} crystalline orientation, with the stress-enhanced DEPMOS transistor structure 600 (e.g., the direction 615 of current flow) being oriented in the <110> direction—e.g., by rotating the substrate by 45 degrees.

The substrate 602, the buried layer 604, the epitaxial layer 606, the STI regions 608, the gate dielectric layer 612, the gate electrode 614, the silicide layers 628, the PMD etch stop layer 630, the PMD layer 632, the contacts 634 and the metal interconnects 636 in the stress-enhanced DEPMOS transistor structure 600 may be formed using similar processing as that described above with respect to formation of the substrate 102, the buried layer 104, the epitaxial layer 106, the STI regions 108, the gate dielectric layer 112, the gate electrode 114, the silicide layers 128, the PMD etch stop layer 130, the PMD layer 132, the contacts 134 and the metal interconnects 136 in the stress-enhanced LDMOS transistor structure 100. The source/drain embedded stressor elements 607 in the stress-enhanced DEPMOS transistor structure 600 may be formed using similar processing as that described above with respect to formation of the source/drain embedded stressor elements 207 in the stress-enhanced LDMOS transistor structure 200. The dielectric stress liner 631 in the stress-enhanced DEPMOS transistor structure 600 may be formed using processing similar to that described above with respect to formation of the dielectric stress liner 331 in the stress-enhanced LDMOS transistor structure 300.

The well region 616, the source regions 624, the source-side LDD region 625, the drain regions 626 and the drain drift region 627 in the stress-enhanced DEPMOS transistor structure 600 may be formed using suitably patterned implant masks and associated ion implant processes. The substrate 602, the epitaxial layer 606, the source regions 624, the source-side LDD region 625, the drain regions 626 and the drain drift region 627 may be doped to a first conductivity type (e.g., p-type) while the buried layer 604 and the well region 616 are doped to a second conductivity type (e.g., n-type).

It should be noted that while FIGS. 6A-6C shows the stress-enhanced DEPMOS transistor structure 600 as including three different types of stressor elements (e.g., the source/drain embedded stressor elements 607, the STI regions 608 and the dielectric stress liner 631), in other examples a stress-enhanced DEPMOS transistor structure may utilize any single type of stressor element, such as one of the source/drain embedded stressor elements 607, the STI regions 608 or the dielectric stress liner 631, or any combination of two or more different types of stressor elements, such as the source/drain embedded stressor elements 607 and the STI regions 608 but not the dielectric stress liner 631, the STI regions 608 and the dielectric stress liner 631 but not the source/drain embedded stressor elements 607, or the source/drain embedded stressor elements 607 and the dielectric stress liner 631 but not the STI regions 608.

Although FIG. 6A shows the source regions 624 and the drain regions 626 as being equal in dimension for simplification of illustration of the plan view, the present disclosure is not limited thereto. For example, the dimensions of the source regions 624 and the drain regions 626 vary as per the DEPMOS transistor configuration. Thus, although FIG. 6A shows the sizing of the source regions 624 and the drain regions 626 as being identical, this is not a requirement. Further, one or more of the source/drain region windows (e.g., as shown in FIG. 6A) may be curved.

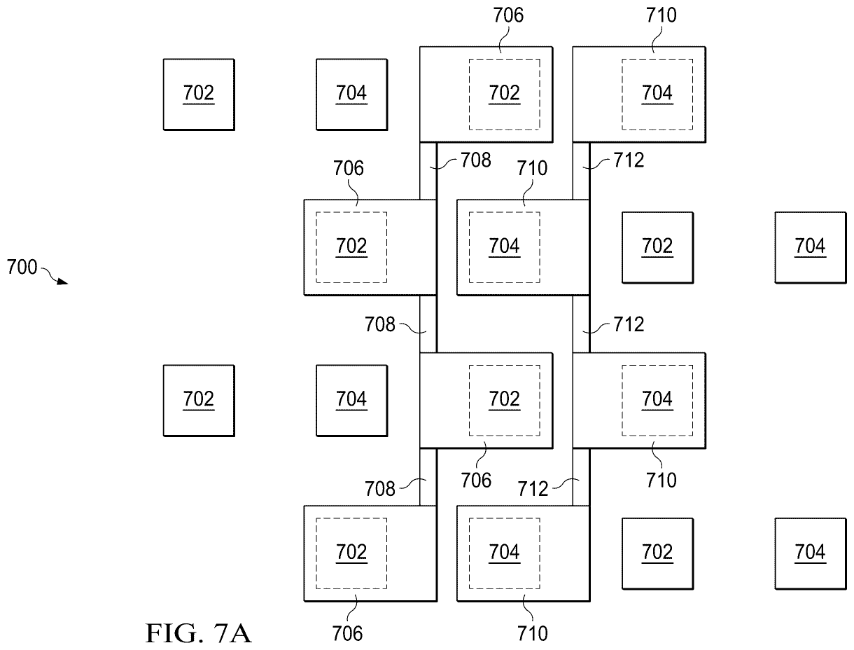

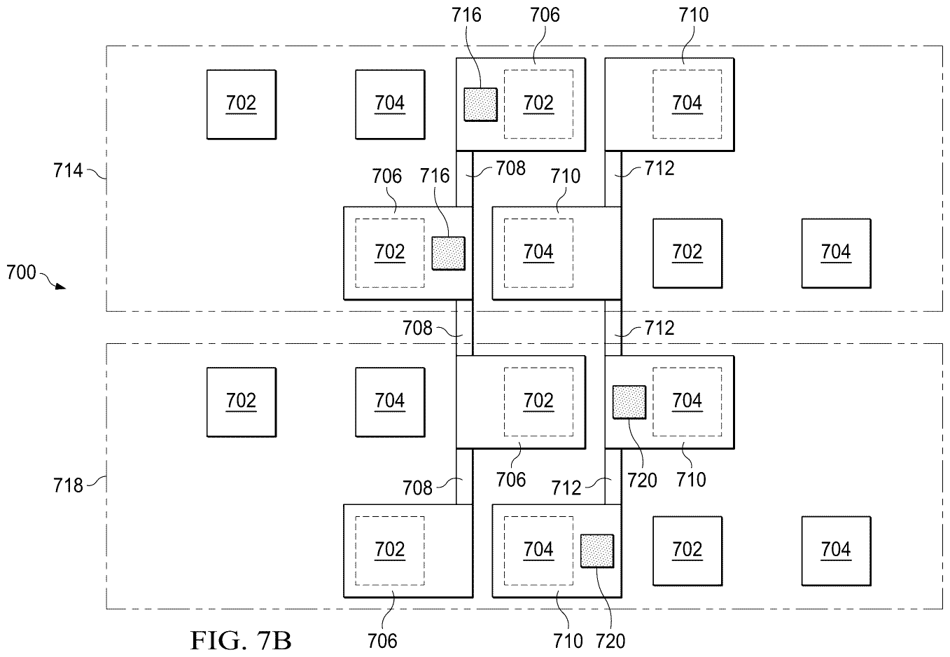

Referring now to FIGS. 7A and 7B, a metallization routing structure 700 is shown which may be utilized for the stress-enhanced LDMOS transistors structures 100, 200, 300 and 400, the stress-enhanced PMOS transistor structure 500, or the stress-enhanced DEPMOS transistors structure 600. The metallization routing structure 700 includes drain regions 702 and source regions 704 which are arranged in a grid layout (e.g., as shown in the plan views of FIGS. 1A, 2A, 3A, 4A, 5A and 6A). FIG. 7A shows a first metallization level of the metallization routing structure 700, which includes a metal layer 706 which contacts ones of the drain regions 702, metal strapping layers 708 connecting portions of the metal layer 706 together, a metal layer 710 which contacts ones of the source regions 704, and metal strapping layers 712 connecting portions of the metal layer 710 together. FIG. 7B shows a second metallization level of the metallization routing structure 700, which includes a metal layer 714 which connects to the metal layer 706 through vias 716, and a metal layer 718 which connects to the metal layer 710 through vias 720.

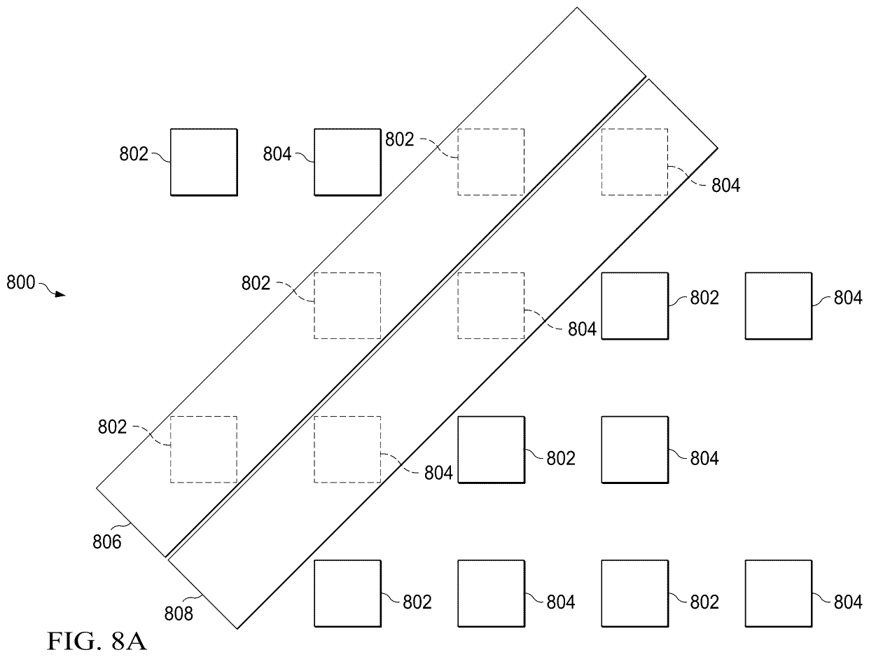

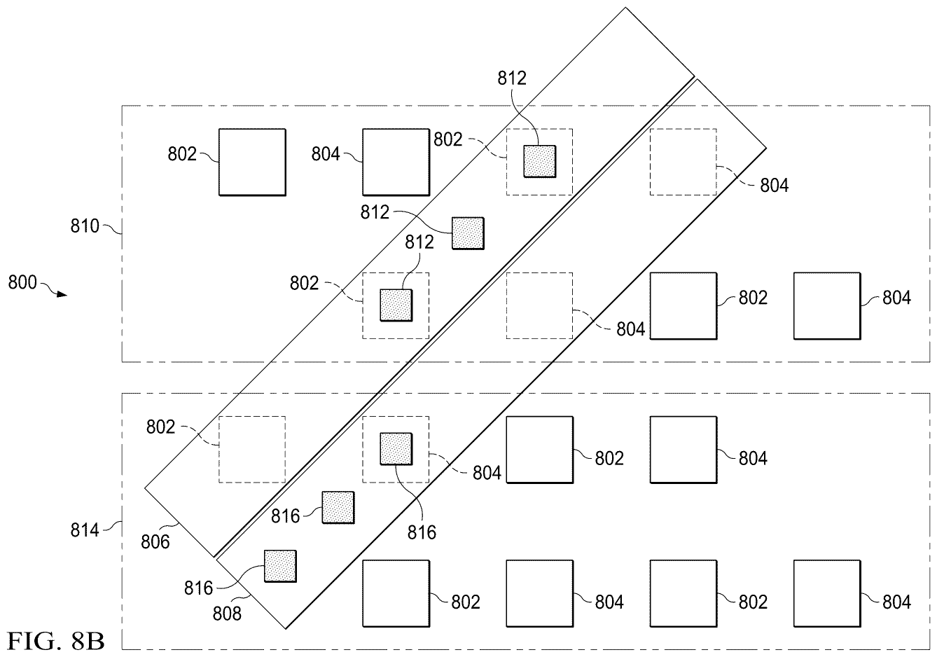

Referring now to FIGS. 8A and 8B, a metallization routing structure 800 is shown which may be utilized for the stress-enhanced LDMOS transistors structures 100, 200, 300 and 400, the stress-enhanced PMOS transistor structure 500, or the stress-enhanced DEPMOS transistors structure 600. The metallization routing structure 800 includes drain regions 802 and source region 804 which are arranged in a grid layout (e.g., as shown in the plan views of FIGS. 1A, 2A, 3A, 4A, 5A and 6A). FIG. 8A shows a first metallization level of the metallization routing structure 800, which includes a metal layer 806 which contacts and connects ones of the drain regions 802, and a metal layer 808 which contacts and connects ones of the source regions 804. FIG. 8B shows a second metallization level of the metallization routing structure 800, which includes a metal layer 810 which connects to the metal layer 806 through vias 812, and a metal layer 814 which connects to the metal layer 808 through vias 816.

In addition, while in accordance with illustrated implementations, various features or components have been shown as having particular arrangements or configurations, other arrangements and configurations are possible. Moreover, aspects of the present technology described in the context of example implementations may be combined or eliminated in other implementations. Thus, the breadth and scope of the description is not limited by any of the above-described implementations.

What is claimed is:

1. A semiconductor device, comprising:
a semiconductor layer;
a first source region disposed in the semiconductor layer;
a first drain region disposed in the semiconductor layer;
a second source region disposed in the semiconductor layer;
a second drain region disposed in the semiconductor layer;
a gate electrode disposed above the semiconductor layer and surrounding the first source region, the first drain region, the second source region and the second drain region; and
a stressor embedded in the semiconductor layer, the stressor being adjacent to the first drain region, the first source region, the second drain region and the second source region;
wherein the first source region and the first drain region are aligned with one another in a first direction, and wherein the second source region and the second drain region are aligned with one another in the first direction; and
wherein the first source region and the second drain region are aligned with one another in a second direction, and wherein the second source region and the first drain region are aligned with one another in the second direction.

2. The semiconductor device of claim 1, wherein the first direction is perpendicular to the second direction.

3. The semiconductor device of claim 1, wherein the stressor is at least partially surrounded by (i) a first channel region in the semiconductor layer connecting the first source region and the first drain region, (ii) a second channel region in the semiconductor layer connecting the first source region and the second drain region, (iii) a third channel region in the semiconductor layer connecting the second source region and the first drain region, and (iv) a fourth channel region in the semiconductor layer connecting the second source region and the second drain region.

4. The semiconductor device of claim 1, wherein the stressor applies compressive stress in the first direction and the second direction.

5. The semiconductor device of claim 1, wherein the stressor comprises one of a plurality of shallow trench isolation regions, the plurality of shallow trench isolation regions each applying compressive stress in the first direction and the second direction.

6. The semiconductor device of claim 1, further comprising a first additional stressor embedded in the first source region, a second additional stressor embedded in the first drain region, a third additional stressor embedded in the second source region, and a fourth additional stressor embedded in the second drain region.

7. The semiconductor device of claim 1, further comprising a stress liner disposed at least partially over at least one of the first source region, the first drain region, the second source region, the second drain region, and the gate electrode.

8. The semiconductor device of claim 1, wherein the semiconductor device comprises at least one laterally-diffused metal-oxide semiconductor (LDMOS) transistor.

9. A semiconductor device, comprising:
a semiconductor layer;
a first source region disposed in the semiconductor layer;
a first drain region disposed in the semiconductor layer;
a second source region disposed in the semiconductor layer;
a second drain region disposed in the semiconductor layer;
a gate electrode disposed above the semiconductor layer and surrounding the first source region, the first drain region, the second source region and the second drain region; and
one or more stressors, each of the one or more stressors being embedded in or disposed over at least one of the first source region, the first drain region, the second source region and the second drain region;
wherein the first source region and the first drain region are aligned with one another in a first direction, and wherein the second source region and the second drain region are aligned with one another in the first direction; and
wherein the first source region and the second drain region are aligned with one another in a second direction, and wherein the second source region and the first drain region are aligned with one another in the second direction.

10. The semiconductor device of claim 9, wherein the one or more stressors comprise a first stressor embedded in the first source region, a second stressor embedded in the first drain region, a third stressor embedded in the second source region, and a fourth stressor embedded in the second drain region.

11. The semiconductor device of claim 10, wherein the first source region, the first drain region, the second source region and the second drain region are n-doped and the first stressor, the second stressor, the third stressor and the fourth stressor comprise silicon carbide.

12. The semiconductor device of claim 10, wherein the first source region, the first drain region, the second source region and the second drain region are p-doped and the first stressor, the second stressor, the third stressor and the fourth stressor comprise silicon germanium.

13. The semiconductor device of claim 9, wherein the one or more stressors comprise a stress liner at least partially disposed over at least one of the first source region, the first drain region, the second source region, the second drain region, and the gate electrode.

14. The semiconductor device of claim 13, wherein the stress liner comprises a single stress liner providing a tensile stressor.

15. The semiconductor device of claim 13, wherein the stress liner comprises a dual stress liner comprising a first stress liner providing a tensile stressor and a second stress liner providing a compressive stressor.

16. The semiconductor device of claim 9, further comprising a shallow trench isolation region disposed in the semiconductor layer, the shallow trench isolation region being at least partially surrounded by (i) a first channel region in the semiconductor layer connecting the first source region and the first drain region, (ii) a second channel region in the semiconductor layer connecting the first source region and the second drain region, (iii) a third channel region in the semiconductor layer connecting the second source region and the first drain region, and (iv) a fourth channel region in the semiconductor layer connecting the second source region and the second drain region.

17. A method comprising:
forming a first source region in a semiconductor layer;
forming a first drain region in the semiconductor layer;
forming a second source region in the semiconductor layer;
forming a second drain region in the semiconductor layer;
forming a gate electrode above the semiconductor layer and surrounding the first source region, the first drain region, the second source region and the second drain region; and
forming one or more stressors;
wherein the first source region and the first drain region are aligned with one another in a first direction, and wherein the second source region and the second drain region are aligned with one another in the first direction;
wherein the first source region and the second drain region are aligned with one another in a second direction, and wherein the second source region and the first drain region are aligned with one another in the second direction; and
wherein the one or more stressors apply stress in the first direction and the second direction.

18. The method of claim 17, wherein forming the one or more stressors comprises forming one or more shallow trench isolation regions disposed in the semiconductor layer, the one or more shallow trench isolation regions applying a compressive stress in the first direction and the second direction.

19. The method of claim 17, wherein forming the one or more stressors comprises forming a first stressor embedded in the first source region, forming a second stressor embedded in the first drain region, forming a third stressor embedded in the second source region, and forming a fourth stressor embedded in the second drain region.

20. The method of claim 17, wherein forming the one or more stressors comprises forming a stress liner at least partially above at least one of the first source region, the first drain region, the second source region, the second drain region, and the gate electrode.
